(19) United States
(12) Patent Application Publication
(10) Pub. No.: US 2006/0071218 A1
(43) Pub. Date: Apr. 6, 2006

(54) Semiconductior multilayer structurehaving inhomogeneous quantum dots, light-emitting diode using same, semiconductor laser diode, semiconductor optical amplifier, and method for manufacturing them

(75) Inventors: Yoshikazu Takeda, Aichi (JP); Yasufumi Fujiwara, Aichi (JP); Ryo Oga, Aichi (JP); WooSik Lee, Aichi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: JAPAN SCIENCE AND TECHNOLOGY AGENCY, Saitama 332-0012 (JP)

(21) Appl. No.: 10/539,635

(22) PCT Filed: Jun. 13, 2003
(86) PCT No.: PCT/JP03/07577

§ 371 Date: Jun. 16, 2005

(30) Foreign Application Priority Data
Dec. 16, 2002 (JP) 2002-364479

(51) Int. Cl. H01L 33/00

(52) U.S. Cl. 257/79

(57) ABSTRACT

A semiconductor multi-layered structure (1) having non-uniform quantum dots formed without requiring lattice strain is of a double hetero junction structure in which an active layer (3) has clad layers (5, 6, 16) laid on its opposite sides, wherein the clad layers are larger in forbidden band than the active layer (3), and the active layer (3) includes at least one layer of non-uniform quantum dots (2) formed without requiring lattice strain and wherein the non-uniform quantum dots in the layer (2) are composed of compound semiconductor material and different from one another in either size or material composition or both. A light emitting diode (15, 15′), a semiconductor laser diode (20) and a semiconductor light amplifier (30) are also provided, each having a semiconductor multi-layered structure (1, 1′) with non-uniform quantum dots. They can emit or amplify light wide in range of wavelengths.

### TECHNICAL FIELD

The present invention relates to a semiconductor multi-layered structure with non-uniform quantum dots and also to a light emitting diode, a semiconductor laser diode and a semiconductor light amplifier using such a structure as well as to a method of making them.

### BACKGROUND ART

In long distance optical communications using quartz fibers to form light transmission lines, bands of 1.3 μm to 1.5 μm are utilized since the wavelength dispersion and transmission loss there become minimum at bands around wavelengths of 1.3 μm and 1.5 μm, respectively.

FIG. 32 is a diagram illustrating the makeup of an Er (erbium) doped fiber optic amplifier (hereinafter referred to as “EDFA”) 90 used for a band around 1.5 μm in transmitting signals in optical communications. As shown the EDFA 90 comprises an Ed doped optical fiber 91, an EDFA excitation semiconductor laser diode (hereinafter referred to as “LD” for the semiconductor laser diode) 92, a fiber coupler 93, a signal LD 95 connected to an input port 94 of the fiber coupler 93, a light isolator 96, and an output port 97.

The EDFALD 92 is required to provide an output power of about 100 mW or more, and the Er doped optical fiber 91 has a length of several to several tens meters. And, the signal LD 95 should have an output power of 20 mW or so. See, for example, “Er doped fiber optic amplifier” edited by Shoichi Sudo, Optoelectronics Co. Ltd., Nov. 21, 1999, pages 6-8.

As for an input signal of the EDFA excitation LD92, the so-called dense wavelength division multiplexing (D-WDM) techniques are growing which are here designed to increase the amount of signals that can be transmitted through the optical fiber by multiplexing the signal LD 95 with many different wavelengths. In this case, if the total light input electric power is increased to increase the multiplicity of signal lights, then achieving a same degree of amplification requires that the EDFA 90 be made higher in its output capability.

The EDFA 90 utilizes the amplifying function by the inner-shell transition of Er³⁺ ions in the Er added optical fiber 91. Raising the degree of amplification by lengthening the Er doped optical fiber 91 is avoided since Er is then not excited efficiently. As a measure to remedy this deficiency, an LD having a resonator structure using a diffraction grating has been disclosed which is designed to make the photoexcitation LD 92 when of a 0.98 μm band larger in its output capability and to make it stable in oscillation wavelength. See, for example, JP 2000-68587 A, page 4 and FIG. 1.

Further, in view of the fact that semiconductor quantum dots exhibit a δ-functional discrete electronic state density, proposals and studies have in recent years been made on an efficient semiconductor laser that has an active layer provided with semiconductor quantum dots and which is high in wavelength or spectral purity, low in threshold value and less in temperature dependency. See the References listed below.

Y. Arakawa and one other, “Multidimensional quantum well laser and temperature dependence of its threshold current”, Appl. Phys., Lett., 1982, Vol. 40, pp. 939-941;

M. Asada and two others, “Gain and threshold of three-dimensional quantum-box lasers”, IEEE, J. Quantum Electron., 1986, QE-22, pp. 1915-1921;

K. J. Vahala, “Quantum-box fabrication tolerance and size limits in semiconductor and their effect on optical gain”, IEEE, J. Quantum Electron., 1988, QE-24, pp. 523-530; and

H. Sasaki, “Quantum wire superlattices and coupled quantum box arrays: a novel method to suppress optical phonon scattering in semiconductors”, Jpn. J. Appl. Phys., 1989, Vol. 28, pp. L134-L136.

To prepare such semiconductor quantum dots, three methods have generally been adopted, namely by:

(1) Selective growth using a processed substrate that is covered with an insulator having fine openings;

(2) Self-formation using the Stranski-Krastanov (S-K) growth mechanism caused by the lattice strain of a substrate and a growth layer (see, for example, N. Stranski, et al, Akad. Wiss. Lit. Mainz, Math-Natur, 1939, Kl. IIb 146, p. 797; Y. Murata, et al, “Self-organizing process techniques”, Baifukan, published Jul. 6, 1997, pp. 264 - 266); and

(3) Self-organization using the atomic layer epitaxial growth (see, for example, JP 2000-340883 A, pages 2-5 and FIG. 1).

Further, a semiconductor laser made by the S-K growth of quantum dots of InAs or InₓGa₁₋ₓAs on a GaAs substrate has already been shown to oscillate continuously at a room temperature though at laboratory level. See, for example, N. Kirstaedter and twelve others “Low threshold, large Tₒ injection laser emission from (InGa)As quantum dots”, Electron Lett., 1994, Vol. 30, pp. 1416-1417; and K. Kamath and four others “Room temperature operation of In_{0.4}Ga_{0.6}As/GaAs self-organized quantum dot lasers”, Electron Lett., 1996, Vol. 32, pp. 1374-1375.

The S-K growth used to make quantum dots by the heteroepitaxial growth process essentially utilizes lattice mismatch. To wit, a three-dimensional island structure is made to obtain quantum dots utilizing the fact that the strain relaxes as the growth layer increases in thickness. Consequently, almost every light emitting device made using the S-K growth has been made on a GaAs substrate, where the device emits light at a wavelength of 1.3 μm at the longest.

There has also been proposed a multi-wavelength oscillating photo semiconductor device with a semiconductor gain waveguide in which quantum dots each of which has one of three different sizes or diameters are had in an active layer region. In this device, quantum dots varied in diameter are quantum dots of InAs or InₓGa₁₋ₓAs made on a GaAs substrate by self-organization using the S-K growth or the atomic layer epitaxial growth process. And, such quantum dots of InₓGa₁₋ₓAs are formed on the GaAs substrate by self-organization using the S-K growth or the atomic layer epitaxial growth process. It is shown, for example, that these quantum dots 21 to 23 have a diameter of 20 nm in average. No oscillation wavelength distribution of such quantum dots is shown, however. See JP 2000-340883 A, supra.

On the other hand, because of poor excitation efficiency of Er in an Er doped optical fiber amplifier, the use of a semiconductor diode amplifier is being considered. For example, a quantum dot laser amplifier with a layer using strain hetero compositional quantum dots and different in size has been disclosed. See, for example, JP 2001-255500 A, FIGS. 6 and 17.

To obtain a light emitting device using quantum dots and operating at a light emission wavelength in a wavelength band of 1.3 μm to 1.5 μm used in optical communications, the present inventors have formed quantum dots on an InP substrate by the droplet epitaxial growth process and observed the resultant photo luminescence at room temperature, as reported in Y. Nonogaki and four others, “InAs dots grown on (001) InP by droplet hetero-epitaxy using OMVPE”, Mat. Sci. & Eng., 1998, Vol. B51, pp. 118-121.

The wavelengths at which the conventional signal and EDFA excitation LDs oscillate vary largely for their operating temperature as the width of a forbidden band as the gap between a conduction and a valence band varies depending on temperature. On the other hand, while in wavelength multiplexing applications for large capacity communication, LDs in which diffraction gratings are configured to form resonators come to be used to stabilize the light emission wavelength, the problem arises that they can only be produced entailing an additional number of process steps and yet in a reduced yield.

Further, in a conventional LD, its operating temperature is maintained constant when the wavelength is to be stabilized. Thus, the temperature control of a LD brought in a thermostatic chamber using a Peltier element for its wavelength stabilization gives rise to the problem that the signal LD and EDFA call for a large and complicated apparatus and further the thermostatic chamber accounts for a larger proportion of the cost. There is added the problem that the thermostatic chamber entails an amount of power consumption as large as several watts or more, namely several tens to one hundred times or more as large as that consumed for the LD itself. There is also brought about the problem that the EDFA using an Er doped optical fiber has its limit to be made smaller. There is further the problem that quantum dots as fine as nm to several tens nm in size in the direction of a crystal plane cannot be formed by the selective growth process when carried out with existing lithography techniques requiring a source of light long in wavelength.

On the other hand, as for strain hetero compositional quantum dots formed utilizing the S-K growth, which are essentially formed by combining semiconductor materials different in lattice constant, the problem arises that there are limits in applicable semiconductor materials and so are in the compositions of quantum dots that can be achieved. Indeed, in the case of GaAs, while the emission of light with a wavelength shorter than 1.3 μm by InAs quantum dots has been realized, no light emission or amplification has been put into reality for a band around 1.3 μm to a band around 1.5 μm.

Further, while in one of the References mentioned above (see K. Kamath and four others “Room temperature operation of In_{0.4}Ga_{0.6}As/GaAs self-organized quantum dot lasers”, Electron Lett., 1996, Vol. 32, pp. 1374-1375), photo luminescence has been observed at the room temperature from InAs quantum dots formed on an InP substrate, no intense luminescence in a band around 1.3 μm to a band around 1.5 μm by forward current injection into a pn diode at the room temperature has been attained.

As discussed above, while semiconductor devices such as LEDs, LDs and semiconductor amplifiers using quantum dots fit for practical use and broad in a wavelength range have been looked for, even an LED having a practical luminous intensity has not been obtained.

### DISCLOSURE OF THE INVENTION

In view of the problems mentioned above it is an object of the present invention to provide a semiconductor multi-layered structure having non-uniform quantum dots which are capable of light emission or amplification in a broad wavelength range and which when formed do not require lattice strain, and also to provide a light emitting diode, a semiconductor laser diode and a semiconductor light amplifier using the same as well as a method of making them.

The present inventors upon having uniquely devised a method of making a non-uniform quantum dot structure that can be formed by droplet hetero-epitaxy without requiring lattice strain, have pioneered in the world in succeeding to observe light emission in a band around 1.3 μm to a band around 1.5 μm from quantum dots by current injection and have reached accomplishing the present invention.

In order to achieve the object mentioned above, there is provided in accordance with the present invention a semiconductor multi-layered structure having quantum dots formed without requiring lattice strain, characterized in that the structure has at least one layer of such non-uniform quantum dots and; the quantum dots in the layer are non-uniform quantum dots individually composed of compound semiconductor and different in one or both of size and compound semiconductor composition.

The present invention also provides a semiconductor multi-layered structure that is of a double hetero junction structure comprising an active layer, and a pair of clad layers laid on opposite sides of the active layer and larger in forbidden band than the active layer, characterized in that the active layer includes at least one layer of non-uniform quantum dots formed without requiring lattice strain whereby the semiconductor multi-layered structure contains non-uniform quantum dots. Then, the quantum dot layer included in the active layer is, preferably, formed of non-uniform quantum dots composed of compound semiconductor and different in one or both of size and compound semiconductor composition. Also, the structure may then be taken that a plurality of such non-uniform quantum dot layers are embedded in the active layer.

Preferably, the quantum dots are made of InAs or GaₓIn₁₋ₓAs (where 0<x≦0.6); and the active layer is made of one of materials selected from the class consisting of InP, AlₓIn₁₋ₓAs (where x=0.27 to 0.65 and it has a forbidden band at room temperature of 0.95 eV to 1.9 eV), GaₓIn₁₋ₓAs_{y}P_{1-y} (where 0<x<1 and 0<y<1), and AlᵤGaᵥIn_{w}As (where u+v+w=1, and it has a forbidden band at room temperature of 0.95 eV to 1.9 eV). Alternatively, the semiconductor multi-layered structure having the non-uniform quantum dots has a substrate made of InP; the quantum dots are made of InAs or GaₓIn₁₋ₓAs (where 0<x≦0.6); the active layer is made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV); and the clad layers are made of AlₓIn₁₋ₓAs (where x=0.42 to 0.48 and it has a forbidden band at room temperature of 1.3 eV to 1.46 eV) or AlₓGa_{y}In_{z}As (where x+y+z=1, and it has a forbidden band at room temperature of 1.3 eV to 1.46 eV). It is desirable that the active layer be lattice-matching with the clad layers.

According to these features of the invention, there are advantageously produced a large number of quantum levels resulting from the non-uniform quantum dot structure formed inside of the semiconductor or semiconductor hetero junction. There is thus provided a semiconductor multi-layered structure having non-uniform quantum dots capable of light emission or amplification in multi wavelengths originating from these quantum levels.

The present invention further provides a light emitting diode using a semiconductor multi-layered structure having non-uniform quantum dots, characterized in that it comprises a p-type semiconductor layer and an n-type semiconductor layer which together form a pn diode; and a layer of non-uniform quantum dots contained in at least one of the semiconductor layers and formed without requiring lattice strain, whereby injecting current into the said pn diode causes the non-uniform quantum dots to be excited, thereby emitting light therefrom in a multi of predetermined wavelengths.

The present invention also provides a light emitting diode using a semiconductor multi-layered structure having non-uniform quantum dots, characterized in that it comprises an active layer containing a semiconductor multi-layered structure having non-uniform quantum dots formed without requiring lattice strain; and a double hetero junction structure comprising the active layer and clad layers formed at opposite sides of the active layer and larger in forbidden band than the active layer, whereby injecting current into the double hetero junction structure causes the non-uniform quantum dots to be excited, thereby emitting light in multi predetermined wavelengths.

In the light emitting diode mentioned above, the quantum dots are non-uniform quantum dots individually composed of compound semiconductor and different in one or both of size and compound semiconductor composition. Also, the said wavelengths may be emission wavelengths including at least wavelengths of any of ultraviolet light, visible light, and infrared light including a 1.3 μm band and a 1.5 μm band. Further, the light emitting diode may have a substrate made of InP; and the quantum dots may be made of InAs or GaₓIn₁₋ₓAs (where 0<x≦0.6). When the dots are made of InAs or GaₓIn₁₋ₓAs (where 0<x≦0.6), the active layer may also be made of one of materials selected from the class consisting of InP, AlₓIn₁₋ₓAs (where x=0.27 to 0.65 and it has a forbidden band at room temperature of 0.95 eV to 1.9 eV), GaₓIn₁₋ₓAs_{y}P_{1-y} (where 0<x<1 and 0<y<1), and AlᵤGaᵥIn_{w}As (where u+v+w=1, and it has a forbidden band at room temperature of 0.95 eV to 1.9 eV).

When, the light emitting diode has a substrate made of InP; the quantum dots are made of InAs or GaₓIn₁₋ₓAs (where 0<x≦0.6); the active layer is made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV), then the clad layers may be made of InP. According to these features, strong light emission can be obtained in multi wavelengths arising from transitions via the quantum levels of non-uniform quantum dots.

The present invention also provides a semiconductor laser diode using a semiconductor multi-layered structure having non-uniform quantum dots, characterized in that it comprises an active layer containing at least one layer of non-uniform quantum dots formed without requiring lattice strain; and a double hetero junction structure comprising the active layer and clad layers formed at opposite sides of the active layer and larger in forbidden band than the active layer, whereby injecting current into the double hetero junction structure causes the non-uniform quantum dots to be excited, thereby bringing about laser oscillations in multi predetermined wavelengths.

In the semiconductor laser diode mentioned above, specifically the quantum dots in the layer are non-uniform quantum dots individually composed of compound semiconductor and different in one or both of size and compound semiconductor composition. Also, these wavelengths are specifically laser oscillation wavelengths including at least wavelengths of any of ultraviolet light, visible light, and infrared light including a 1.3 μm band and a 1.5 μm band.

The semiconductor laser diode has a substrate specifically made of InP; and then the quantum dots may be made of InAs or GaₓIn₁₋ₓAs (where 0<x≦0.6); the active layer may be made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV); and the clad layers may be made of AlₓIn₁₋ₓAs (where x=0.42 to 0.48 and it has a forbidden band at room temperature of 1.3 eV to 1.46 eV) or AlₓGa_{y}In_{z}As (where x+y+z=1, and it has a forbidden band at room temperature of 1.3 eV to 1.46 eV). Preferably, the active layer is lattice-matching with the clad layers. According to these features of the invention, laser light can be obtained in multi wavelengths arising from transitions via a plurality of quantum levels of a layer of non-uniform quantum dots included in the active layer.

The present invention also provides a semiconductor light amplifier using a semiconductor multi-layered structure having non-uniform quantum dots, characterized in that it comprises an active layer containing at least one layer of non-uniform quantum dots formed without requiring lattice strain; and a double hetero junction structure comprising the active layer and clad layers formed at opposite sides of the active layer and larger in forbidden band than the active layer, whereby injecting current into the double hetero junction structure causes the non-uniform quantum dots to be excited, thereby amplifying light in multi predetermined wavelengths incident externally of the double hetero junction structure.

In the semiconductor light amplifier mentioned above, the quantum dots in the layer are specifically non-uniform quantum dots individually composed of compound semiconductor and different in one or both of size and compound semiconductor composition. The said wavelengths may be amplification wavelengths including at least wavelengths of any of ultraviolet light, visible light, and infrared light including a 1.3 μm band and a 1.5 μm band.

Also, the semiconductor light amplifier may have a substrate made of InP; the quantum dots may be made of InAs or GaₓIn₁₋ₓAs (where 0<x≦0.6); the active layer may be made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV); and the clad layers may be made of AlₓIn₁₋ₓAs (where x=0.42 to 0.48 and it has a forbidden band at room temperature of 1.3 eV to 1.46 eV) or AlₓGa_{y}In_{z}As (where x+y+z=1, and it has a forbidden band at room temperature of 1.3 eV to 1.46 eV). Preferably, the active layer is lattice-matching with the clad layers.

According to these features, light amplification can be attained in multi wavelengths arising from transitions via a plurality of quantum levels of a layer of non-uniform quantum dots included in the active layer.

The present invention further provides a method of making a semiconductor device using a semiconductor multi-layered structure having non-uniform quantum dots in a non-uniform quantum dot structure, characterized in that it includes the step of fabricating the non-uniform quantum dot structure for the semiconductor device by an epitaxial growth process that does not require lattice strain in forming non-uniform quantum dots. The said semiconductor device may be any one of a light emitting diode, a semiconductor laser diode and a semiconductor light amplifier.

The said epitaxial growth process may be any one of MOCVD, MBE, gas source MBE and MOMBE processes and a layer of the non-uniform quantum dots may be fabricated by a droplet epitaxial growth process which does not require lattice strain in forming non-uniform quantum dots. The non-uniform quantum dot layer may be formed by an auto-terminating mechanism in said droplet epitaxial growth process. Specifically, the said epitaxial growth process is MOCVD and the non-uniform quantum dot layer is formed by droplet epitaxial growth at a growth temperature lower than that at which other growth layers in the structure are formed.

According to the methods mentioned above, using the droplet epitaxial growth process can form a semiconductor multi-layered structure including a structure of non-uniform quantum dots which when formed do not require lattice strain, thus enabling a light emitting diode, a semiconductor laser diode and a semiconductor light amplifier to be made which can emit or amplify light in a large number of wavelengths.

### BRIEF DESCRIPTION OF THE DRAWINGS

The present invention will better be understood from the following detailed description and the drawings attached hereto showing certain illustrative forms of implementation of the present invention. In this connection, it should be noted that such forms of implementation illustrated in the accompanying drawings hereof are intended in no way to limit the present invention but to facilitate an explanation and understanding thereof. In the drawings,

FIG. 1 is a typical view illustrating a cross section of a semiconductor multi-layered structure having non-uniform quantum dots according to a first aspect of the present invention;

FIG. 2 is a typical view illustrating a cross section of a modification of the semiconductor multi-layered structure having non-uniform quantum dots according to the first aspect of the present invention;

FIG. 3 shows diagrams typically illustrating a single quantum dot in a non-uniform quantum dot layer in a semiconductor multi-layered structure having non-uniform quantum dots according to the present invention;

FIG. 4 shows diagrams illustrating energy difference, refractive index distribution and the band structure of a pn junction in its forward direction for a double hetero junction structure as a semiconductor multi-layered structure having non-uniform quantum dots according to the first aspect of the present invention;

FIG. 5 is a view illustrating a cross section of an LED using a semiconductor multi-layered structure having non-uniform quantum dots according to a second aspect of the present invention;

FIG. 6 is a diagrammatic cross sectional view of an LD using a semiconductor multi-layered structure having non-uniform quantum dots according to a third aspect of the present invention;

FIG. 7 is a diagrammatic cross sectional view taken along the line A-A in FIG. 6;

FIG. 8 is a diagrammatic cross sectional view of a semiconductor light amplifier using a semiconductor multi-layered structure having non-uniform quantum dots according to a fourth aspect of the present invention;

FIG. 9 is a diagrammatic cross sectional view taken along the line B-B in FIG. 8;

FIG. 10 shows cross sectional views of a semiconductor device illustrating a method of making a semiconductor multi-layered structure having non-uniform quantum dots according to a fifth aspect of the present invention;

FIG. 11 shows partial cross sectional views of growth layers in the method of making the semiconductor multi-layered structure having non-uniform quantum dots according to the fifth aspect of the present invention;

FIG. 12 is a diagram illustrating the makeup of a MOCVD apparatus for use in the method of making a semiconductor device according to the fifth aspect of the present invention;

FIG. 13 shows graphs illustrating a relationship between growth temperature and gas flow rate during crystal growth for a semiconductor multi-layered structure 1′ with a non-uniform quantum dot structure;

FIG. 14 shows a surface observed with an atomic force microscope, of a structure of non-uniform quantum dots grown by a droplet epitaxial growth process;

FIG. 15 is a graph illustrating sizes of non-uniform quantum dots formed by the droplet epitaxial growth process;

FIG. 16 shows graphs illustrating distributions of diameters and heights of small dots of non-uniform quantum dots formed by the droplet epitaxial growth process;

FIG. 17 is a graph illustrating luminous emission intensity by photo luminescence of a semiconductor multi-layered structure having non-uniform quantum dots according to the present invention;

FIG. 18 shows graphs illustrating a relationship between the growth temperature and the gas flow rate during crystal growth for an LED using a semiconductor multi-layered structure having non-uniform quantum dots according to the present invention;

FIG. 19 is a table giving specific values for the flow rate of gas supply for successive layers grown in the structure shown in FIG. 18;

FIG. 20 is a graph illustrating emission spectra at room temperature for an LED using a semiconductor multi-layered structure having non-uniform quantum dots according to the present invention;

FIG. 21 is a graph illustrating an IL characteristic as a relationship between the electric current and the intensity of emission by current injection for an LED using a semiconductor multi-layered structure having non-uniform quantum dots according to the present invention;

FIG. 22 shows cross sectional views illustrating process steps of making a semiconductor multi-layered structure using a non-uniform quantum dot structure as shown in Example 3;

FIG. 23 is a table giving growth conditions under which a non-uniform quantum dot layer of Example 3 is formed by the droplet epitaxial growth process;

FIG. 24 is a graph illustrating a relationship between the TMIn supply time and the in-plane density of non-uniform quantum dots in the structure of Example 3;

FIG. 25 is a cross sectional view of an LED using a semiconductor multi-layered structure having non-uniform quantum dots according to Example 4 of the present invention;

FIG. 26 is a graph illustrating an emission spectrum for forward injection at room temperature, of an LED using a semiconductor multi-layered structure having non-uniform quantum dots according to Example 4 of the present invention;

FIG. 27 is a time chart illustrating a relationship between the growth temperature and the gas flow rate during the crystal growth of an LED in Example 5 of the present invention;

FIG. 28 is a graph illustrating a relationship between the TMIn supply rate and the in-plane density of non-uniform quantum dots in the structure in Example 5 of the present invention;

FIG. 29 is a graph illustrating an EL emission spectrum for forward injection at room temperature, of an LED using a semiconductor multi-layered structure having non-uniform quantum dots according to Example 5 of the present invention;

FIG. 30 is a time chart illustrating a relationship between the growth temperature and the gas flow rate during the epitaxial crystal growth of a semiconductor laser diode 20 in Example 6 of the present invention;

FIG. 31 is a chart illustrating a band structure of a semiconductor laser diode using a semiconductor multi-layered structure having non-uniform quantum dots according to Example 6 of the present invention; and

FIG. 32 is a diagram illustrating the makeup of an Er doped optical fiber amplifier for a 1.5 μm band used for signal transmissions in optical communication.

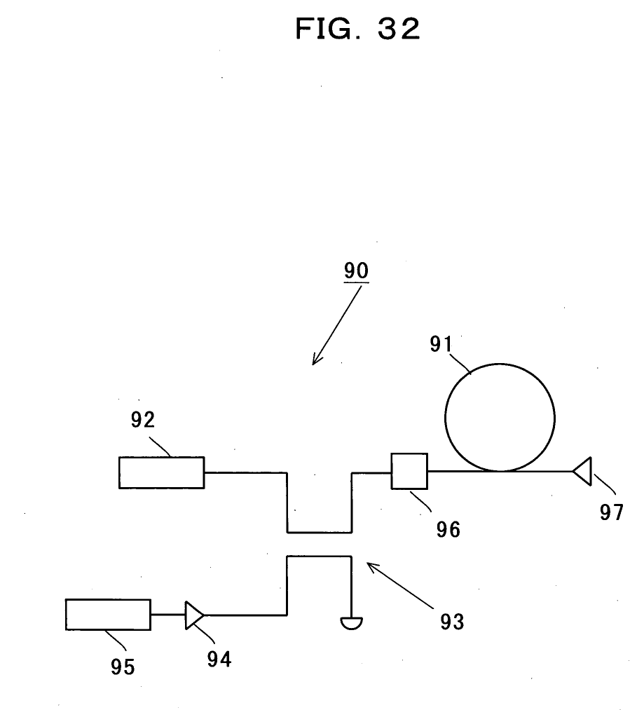

### BEST MODE FOR CARRYING OUT THE INVENTION

Hereinafter, the present invention will be described in detail with reference to certain suitable forms of implementation thereof illustrated in the drawing figures.

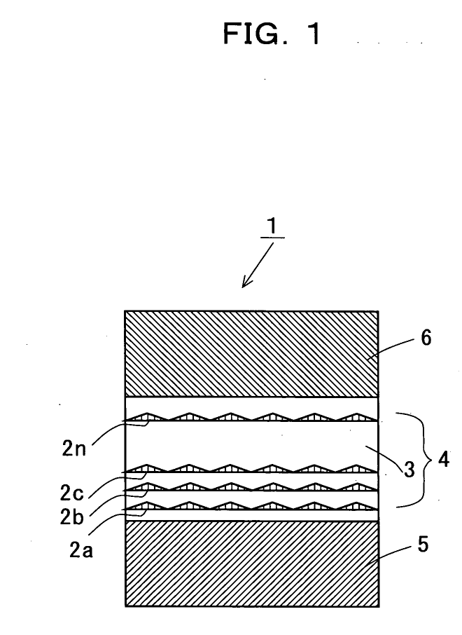

At the outset, a semiconductor multi-layered structure having non-uniform quantum dots in accordance with a first aspect of the present invention will be shown. FIG. 1 is a typical view illustrating a cross section of a semiconductor multi-layered structure having non-uniform quantum dots according to the first aspect of the present invention. The semiconductor multi-layered structure 1 having non-uniform quantum dots in accordance with the present invention is of a double hetero structure provided with an active layer 4 and clad layers 5 and 6 disposed at the opposite sides of the active layer 4 wherein layers 2 (2a-2n) of non-uniform quantum dots formed without requiring lattice strain are embedded in a semiconductor layer 3 larger in forbidden band than the non-uniform quantum dot layers 2 to form the active layer 4 while the clad layers 5 and 6 are of a semiconductor larger in forbidden band than the semiconductor layer 3. The clad layers 5 and 6 may be n- and p-type semiconductor layers, respectively, or undoped semiconductor layers which are not doped with impurity.

The semiconductor multi-layered structure 1 having non-uniform quantum dots which are formed without requiring lattice strain (hereinafter simply referred to as “non-uniform quantum dots”) can be fabricated, for example, by epitaxially growing n-type clad layer 5 larger in forbidden band on the n-type semiconductor substrate, the active layer 4 having the non-uniform quantum dot layers 2 successively multi-layered, and p-type clad layer 6 larger in forbidden band, successively.

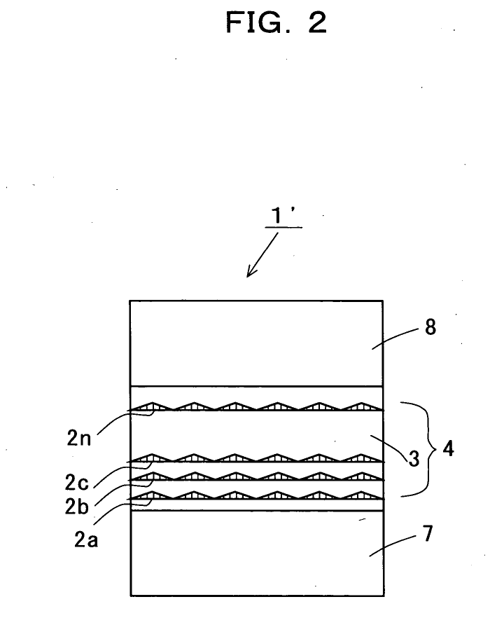

Mention is next made of a modification of the semiconductor multi-layered structure having non-uniform quantum dots according to the first aspect of the present invention. FIG. 2 is a typical view illustrating a cross section of a modification of the semiconductor multi-layered structure having non-uniform quantum dots in accordance with the first aspect of the present invention. The double hetero structure shown in FIG. 2, of a semiconductor multi-layered structure 1′ having non-uniform quantum dots formed without requiring lattice strain is identical to that of the semiconductor multi-layered structure 1 having non-uniform quantum dots shown in FIG. 1 except that its layers 7 and 8 corresponding to the clad layers 5 and 6 in the FIG. 1 structure are formed of the same material as the semiconductor layer 3. These semiconductor layers 7 and 8 at the opposite sides of the active layer may, here again, be n- and p-type semiconductor layers, respectively, or undoped semiconductor layers which are not doped with impurity.

In the semiconductor multi-layered structure 1, 1′ having non-uniform quantum dots which are formed without requiring lattice strain, the semiconductor layer 3 larger in forbidden band may be formed of InP or Al_{0.26}Ga_{0.21}In_{0.53}As and the non-uniform quantum dot layers 2 may be formed of InAs.

The layer 4 with non-uniform quantum dots is thus formed to contain one or more, e.g., twenty layers 2 of non-uniform quantum dots formed without requiring lattice strain.

In the semiconductor multi-layered structure 1, 1′ according to the present invention, non-uniform quantum dots that can be formed in the absence of lattice strain caused by lattice mismatch are formed along a hetero junction formed between a semiconducting material forming a quantum dot layer 2 and a semiconductor layer 3 large in forbidden band. While preferably these semiconducting materials are identical in lattice constant, namely take lattice match, a lattice mismatch, due to lattice strain, within 1% to 3.5% is generally acceptable. Such a semiconductor multi-layered structure 1, 1′ having non-uniform quantum dots can be made by a droplet epitaxial growth process which does dot require lattice strain when forming quantum dots as will be described below. A non-uniform quantum dot structure 2 in an active layer 4 having non-uniform quantum dot layers 2 may use and be composed of such as GaₓIn₁₋ₓAs (where 0<x≦0.6) besides InAs.

Also, in the active layer 4 composed of the semiconductor layer 3 larger in forbidden band than non-uniform quantum dot structures 2, the semiconductor layer 3 large in forbidden band may use and be composed of any one of InP, AlₓIn₁₋ₓAs (where x=0.27 to 0.65 and the forbidden band at the room temperature is 0.95 eV to 1.9 eV), GaₓIn₁₋ₓAs_{y}P_{1-y} (where 0<x<1 and 0<y<1), AlᵤGaᵥIn_{w}As (where u+v+w=1 and the forbidden band at the room temperature is 0.95 eV to 1.9 eV). Further, the substrate may then use InP.

The clad layers 5 and 6 should advantageously be composed of a material that is larger in forbidden band than the active layer 4 and that can provide a difference in forbidden band ΔEg generally of 0.3 eV to 0.4 eV. Also, the clad layers 5 and 6 should preferably be smaller in index of refraction than the active layer 4 and provide a difference in index of refraction Δn generally of 0.15 or more for light entrapment. The clad layer 5, 6 may use and be composed of AlₓIn₁₋ₓAs (where x=0.42 to 0.48 and the forbidden band at the room temperature then ranges between 1.3 eV and 1.46 eV) or may be made of AlₓGa_{y}In_{z}As (where x+y+z=1, the forbidden band at the room temperature then ranging between 1.3 eV and 1.46 eV). It may, for example, use and be composed of Al_{0.40}Ga_{0.07}In_{0.53}As.

In the band structure as the double hetero structure made of the clad layers 5 and 6 and the active layer 4, a combination of materials forming the active and clad layers is desirably such that the clad layer 5, 6 has a large energy difference both in conduction and valence bands from the active layer 4.

Further, the active layer 4 and the clad layer 5, 6 in the double hetero structure should preferably be identical in lattice constant or take a lattice match. The state that a lattice match is taken is here intended to mean that at least a lattice mismatch is within 1% to 3.5%. Also, the active layer 4 having non-uniform quantum dot layers 2 and the clad layer 5, 6 are composed of a material such as one of GaN, AlN and InN as III-V group compound semiconductors larger in forbidden band than InP, or a mixed crystal of these compound semiconductors, or a combination of them.

It follows, therefore, that by combining semiconductor materials essentially different in lattice constant in forming quantum dots conventionally sought to be made of a composition of a deformed hetero system utilizing the S-K growth, the present invention has successfully overcome the restrictions met by the prior art in finding applicable semiconductor materials and realizable quantum dot compositions. Thus, a semiconductor multi-layered structure 1, 1′ having non-uniform quantum dots in accordance with the present invention, which can be formed without entailing lattice strain, is easy to manufacture with good crystal quality.

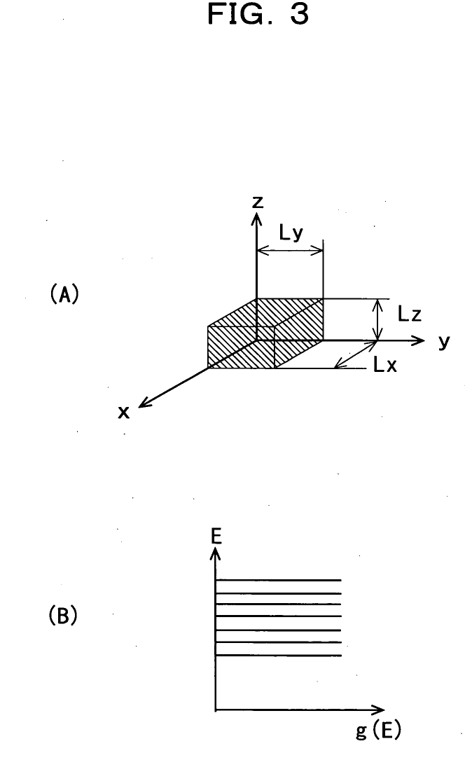

FIG. 3 shows diagrams typically illustrating a single quantum dot in a non-uniform quantum dot layer 2 in a semiconductor multi-layered structure 1 having non-uniform quantum dots according to the present invention. FIGS. 3(A) and 3(B) illustrate the structure of a non-uniform quantum dot and its energy state density, respectively.

In FIG. 3(A), the quantum dot is shown having dimensions or lengths Lx, Ly and Lz in the directions of x, y and z axes, respectively. Here, the z axis extends perpendicular to the cross sectional structure shown in FIG. 1. Electron energy of the quantum dot is expressed by equation (1) below (see, for example, “Superlattice Hetero Structure Devices”, edited by Hiroyuki Sakaki under the supervision of Reona Esaki, K. K. Kogyo Chosakai, Sep. 10, 1988, page 71).

$$E ( n , m , l ) = ( \frac{{h}^{2}}{8 {π}^{2} {m}^{*}} ) \cdot \{ {( \frac{n π}{{L}_{z}} )}^{2} + {( \frac{m π}{{L}_{y}} )}^{2} + {( \frac{l π}{{L}_{x}} )}^{2} \} \qquad ( 1 )$$

where n, m and l are quantum numbers, h the Plank's constant and m* the effective mass of a semiconductor forming the quantum dot.

When in a ground state where n=m=l=1, the electron energy can be found if Lₓ, L_{y} and L_{z} are given.

In a non-uniform quantum dot layer 2, lengths Lₓ, L_{y} and L_{z} of quantum dots have their respective distributions. Further as for a non-uniform quantum dot layer 2, as when In and Ga droplets are used in the droplet epitaxial growth process to form GaₓIn₁₋ₓAs, it is possible to change m* in the equation (1) above if layers 2 spatially different in composition such as GaₓIn₁₋ₓAs are formed. Also, if the non-uniform quantum dot is formed of a mixed crystal such as GaₓIn₁₋ₓAs, the non-uniform quantum dot may have both its size and composition x varied, to be uneven in size and heterogeneous in composition.

It follows, therefore, that unlike a uniform or homogenous quantum dot layer, a non-uniform quantum dot layer 2 in accordance with the present invention can have a plurality of electron energy levels, namely a plurality of quantum levels (see FIG. 3(B)). Then, the non-uniform quantum dot layer 2 if its constituent material is suitably selected is made capable of emitting multi-wavelength light including at least any of wavelengths of ultraviolet light, visible light, and infrared light in a 1.3 μm and a 1.5 μm band. Then, energizing with an external light or electron beam large in energy enough than these quantum levels allows light emission in a broad range of wavelengths.

Mention is next made of an operation of a semiconductor multi-layered structure having non-uniform quantum dots according to the first aspect of the invention described above.

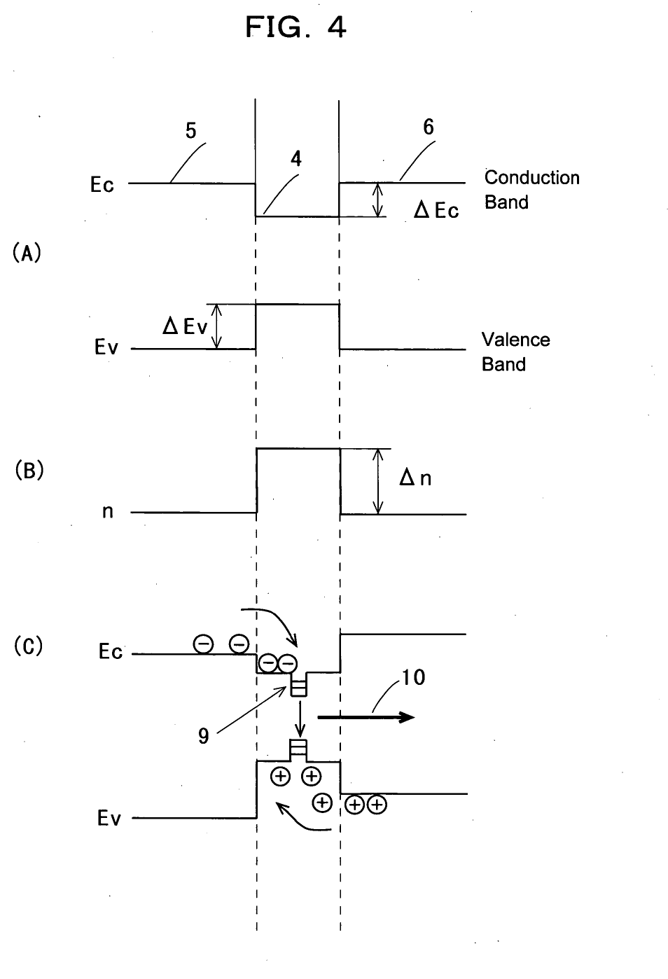

FIG. 4 shows diagrams illustrating energy difference, refractive index distribution and the band structure of a pn junction in its forward direction for a double hetero structure as a semiconductor multi-layered structure having non-uniform quantum dots according to the first aspect of the present invention. In FIG. 4, (A), (B) and (C) illustrate a forbidden band difference, namely a band gap energy difference in a region of the hetero junction; changes in index of refraction; and luminous mechanism when carriers are injected in forward direction into the pn junction in the double hetero structure. In the Figure, the n-type clad layer 5 lies at the left hand side.

In FIG. 4(A), energy difference in conduction band and energy difference in valence band between the active layer 4 and the n-type or p-type clad layer 5 or 6 are shown to be ΔEc and ΔEv, respectively.

Here, the semiconductor layer 3 forming the active layer 4 can be Al_{0.26}Ga_{0.21}In_{0.53}As. Also, the n-type and p-type clad layers 5 and 6 can be Al_{0.40}Ga_{0.07}In_{0.53}As. Then, the forbidden band of Al_{0.26}Ga_{0.21}In_{0.53}As and Al_{0.40}Ga_{0.07}In_{0.53}As being 1.18 eV and 1.43 eV, respectively, the band gap energy difference ΔEg here is 0.25 eV.

FIG. 4(B) shows refraction index distribution of the double hetero junction, illustrating that light entrapment occurs because the active layer 4 is larger in index of refraction than the clad layer (5, 6) by Δn. The indices of refraction of Al_{0.26}Ga_{0.21}In_{0.53}As and Al_{0.40}Ga_{0.07}In_{0.53}As being 3.35 and 3.20, respectively, Δn=0.15.

FIG. 4(C) illustrates light emission mechanism when carriers are injected forwards with an electric current. Electrons injected from the n-type clad layer 5 and positive holes injected from the p-type clad layer 6 are entrapped in the active layer 4. Here, the double hetero structure having the n-type and p-type clad layers 5 and 6 disposed across the active layer 4 allows electrons and positive holes to be efficiently injected into the active layer 4. The electrons and positive holes entrapped in the active layer 4 transitions via a plurality of quantum energy levels 9 of the non-uniform quantum dot structure 1 in the active layer 4, thereby bringing about light emission 10 from the non-uniform quantum dot structure 2. Further, this light emission is confined within the active layer 4 efficiently by a difference in index of refraction in the double hetero structure.

Moreover, in the modified semiconductor multi-layered structure 1′ having non-uniform quantum dots in accordance with the present invention, the operation other than the light entrapment likewise applies whereby light emission 10 from the non-uniform quantum dot structure 2 is brought about. The light emission 10 by the non-uniform quantum dot structure, which is due to a plurality of quantum energy levels 9 in the non-uniform quantum dot structure 1, 1′, is effected with wavelengths in a broad band. The excitation of electrons and positive holes in the active layer 4 may be effected injection forwards as mentioned above or alternatively backwards across the pn junctions, by avalanche injection, or external light or electron beam irradiation.

Mention is next made of an LED using a semiconductor multi-layered structure having non-uniform quantum dots in accordance with a second aspect of the present invention.

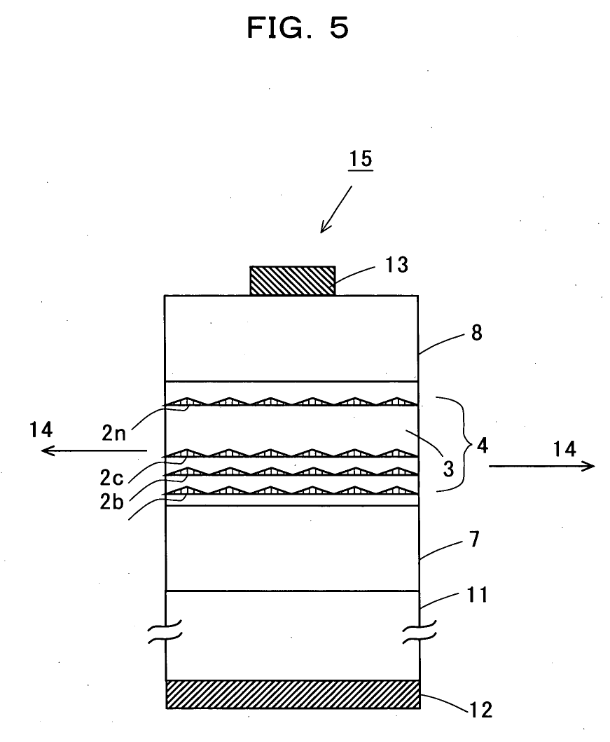

FIG. 5 is a view illustrating a cross section of an LED using a semiconductor multi-layered structure having non-uniform quantum dots according to a second aspect of the present invention. As shown in the Figure, an LED 15 using a semiconductor multi-layered structure having non-uniform quantum dots in accordance with the present invention here includes an n-type semiconductor substrate 11 on which is built the semiconductor multi-layered structure 1′ having non-uniform quantum dots formed without requiring lattice strain. The n-type semiconductor substrate 11 and the p-type semiconductor layer 8 are formed with an n-type and a p-type ohmic electrode 12 and 13, respectively. The n-type semiconductor substrate 11 and the n-type and p-type semiconductor layers 7 and 8 use and are composed of a semiconductor or semiconductors larger in forbidden band than a semiconductor that forms the quantum dots in the semiconductor multi-layered structure 1 having non-uniform quantum dots in accordance with the present invention. They may be composed of InP if the quantum dots are made of InAs.

A multi-layered structure of LED 15 may be made, for example, by depositing an n-type semiconductor layer 7 as a buffer layer composed of InP with an impurity density of 1×10¹⁷ to 5×10¹⁸ cm⁻³ to a thickness of 0.001 μm to 2 μm, an active layer 4 having non-uniform quantum dots to a thickness of 0.1 μm to 3 μm and a p-type semiconductor layer 8 of p-type InP with an impurity density of 1×10¹⁸ to 5×10¹⁹ cm⁻³ to a thickness of 0.5 μm to 5 μm, successively on an n-type InP substrate 11 of 250 μm to 500 μm thick and with an impurity density of 1×10¹⁸ to 1×10¹⁹ cm⁻³.

Mention is made of an operation of the LED 15 using the semiconductor multi-layered structure using non-uniform quantum dots according to the present invention. When electric current is passed forwards through the LED 15 using the semiconductor multi-layered structure having non-uniform quantum dots according to the present invention, electrons and positive holes are injected into the active layer 4 having non-uniform quantum dots, and the transition of electrons via a large number of non-uniform quantum dots causes the LED to emit light 14 with multiple wavelengths high in luminous intensity. This light emission 14 by the LED, which is from a large number of quantum levels by non-uniform quantum dots, can be wide in range of wavelengths. Then, with the non-uniform quantum dot layer suitably selected in its constituent material, a multi-wavelength light can be emitted at least containing wavelengths in any of ultraviolet to visible light ranges and infrared light range of a 1.3 μm and a 1.5 μm band.

Mention is next made of an LD using a semiconductor multi-layered structure having non-uniform quantum dots according to a third aspect of the present invention.

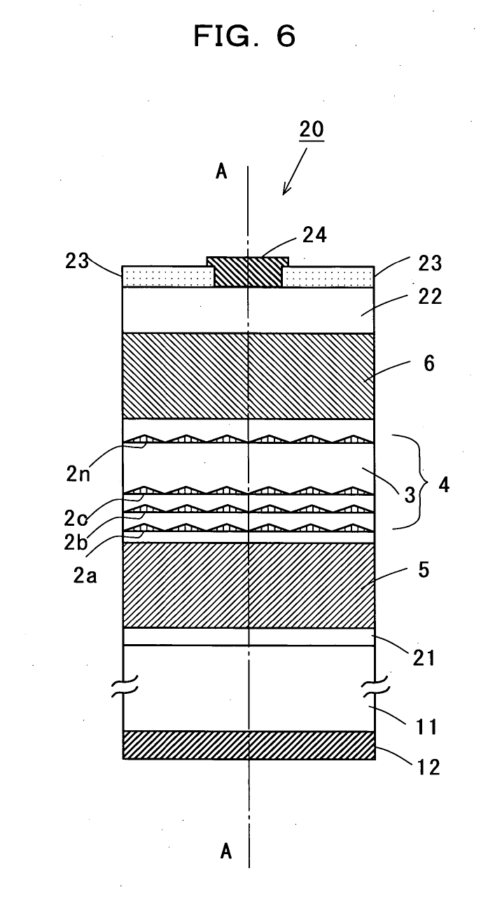

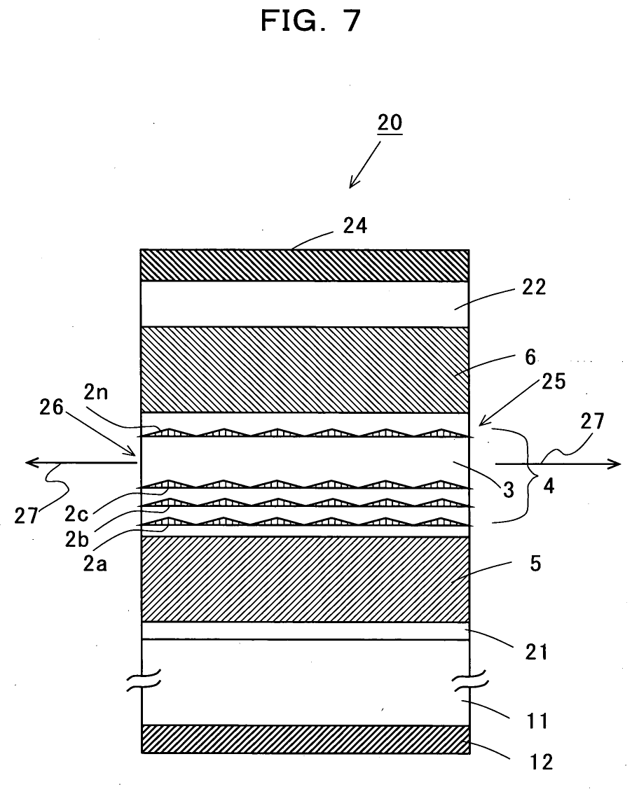

FIG. 6 is a diagrammatic cross sectional view of an LD using a semiconductor multi-layered structure having non-uniform quantum dots in accordance with the present invention. FIG. 7 is a diagrammatic cross sectional view taken along the line A-A in FIG. 6. As shown in the Figures, an LD 20 using a semiconductor multi-layered structure having non-uniform quantum dots includes a buffer layer 21 deposited on an n-type semiconductor substrate 11, and on the buffer layer 21 a semiconductor multi-layered structure 1 comprising an n-type clad layer 5, an active layer 4 containing non-uniform quantum dot structural layers formed without requiring lattice strain and a p-type clad layer 6, and then has a p⁺-type semiconductor layer 22 deposited on the latter.

Here, the n-type semiconductor substrate 11, the buffer layer 21 and the p⁺-type semiconductor layer 22 can be formed of an identical semiconductor which is assumed to have a forbidden band Eg1. Then, assuming also that the n-type and p-type semiconductor clad layers 5 and 6, the semiconductor layer 3 in the active layer and the semiconductor forming the non-uniform quantum dots have forbidden bands Eg2, Eg3 and Eg4, respectively, it may suffice if these forbidden bands have relationship: Eg1>Eg2>Eg3>Eg4.

The n-type semiconductor substrate 11 is formed with an n-layer ohmic electrode 12. Further, the p⁺-type semiconductor layer 22 has an insulating film 23 deposited thereon which has an opening in the form of a stripe in which is formed a stripe electrode 24 as a p-layer ohmic electrode 24. The n-type semiconductor substrate 11, the buffer layer 21 and the p⁺-type semiconductor layer 22 may be of an identical semiconductor. Further, the buffer layer 21 may be dispensed with if a good n-type clad layer 5 can well be formed directly on the n-type semiconductor substrate 11. It is then desirable or essential that a lattice match be taken of the n-type clad layer with the n-type semiconductor substrate 11.

The LD 20 using a semiconductor multi-layered structure having non-uniform quantum dots in accordance with the present invention differs from the LED 15 in that the ohmic electrode for the p⁺-type semiconductor layer 22 is formed as the stripe electrode 24 to intensify the electric current passed through the active layer 4 containing non-uniform quantum dots and that end faces 25 and 26 are provided that form the reflecting surfaces of a Fabry-Perot resonator for bringing about laser oscillations (see FIG. 7). By the way, the structure of the LD 20 shown in FIG. 6 may be modified to make the structure of LED 15 if a p-layer ohmic electrode not made in the form of the stripe 24 is provided on a front face of the device.

A multi-layered structure of the LD 20 may be formed, for example, by epitaxially growing a buffer layer 21 of n-type InP with an impurity density of 1×10¹⁷ to 5×10¹⁸ cm⁻³ to a thickness of 0.001 μm to 2 μm, a n-type clad layer 5 of n-type Al_{0.40}Ga_{0.07}In_{0.53}As with an impurity density of 1×10¹⁷ to 5×10¹⁸ cm⁻³ to a thickness of 0.5 μm to 3 μm, an active layer 4 of a non-uniform quantum dot structure to a thickness of 0.1 μm to 3 μm wherein the non-uniform quantum dot structure 2 has one to twenty layers of non-uniform quantum dots of InAs formed without requiring lattice strain in a semiconductor layer 3 of Al_{0.}Ga_{0.07}In_{0.53}As large in forbidden band, a p-type clad layer 6 of p-type Al_{0.40}Ga_{0.07}In_{0.53}As with an impurity density of 1×10¹⁷ to 5×10¹⁸ cm⁻³ to a thickness of 0.5 μm to 3 μm and a p⁺-type semiconductor layer 22 of p-type InP with an impurity density of 1×10¹⁸ to 5×10¹⁹ cm⁻³ to a thickness of 0.5 μm to 5 μm, successively on an n-type InP substrate 11 of 250 μm to 500 μm thick and with an impurity density of 1×10¹⁸ to 1×10¹⁹ cm⁻³.

Mention is made of an operation of the LD 20 using a semiconductor multi-layered structure having non-uniform quantum dots in accordance with the present invention.

The LD 20 using a semiconductor multi-layered structure having non-uniform quantum dots in accordance with the present invention has a Fabry-Perot resonator formed with a pair of mirrors constituted by planes of cleavage on opposite end faces 25 and 26 of the active layer 4 having the non-uniform quantum dot structure formed without requiring lattice strain. Forward current injection causes electrons and positive holes to be injected into the active layer 4 having the non-uniform quantum dot structure, and the electrons transition via a large number of quantum levels in the non-uniform quantum dot structure. As lights occurring from these levels of the non-uniform quantum dot structure advance through the active layer 4 having the non-uniform quantum dot structure, they are made even in phase successively and inductively emitted, and as a result of their repeated reflections at the opposite end faces of the active layer 4 having the non-uniform quantum dot structure, multi-wavelength laser oscillations are brought about.

Moreover, increasing the current passed through the LD 20 causes the LD 20 to increase its light output while reducing the half-value breadth of each wavelength of oscillations and thereby to initiate laser oscillations 27 multiple in wavelength and broadened in range of wavelengths. Then, with the non-uniform quantum dot layers 2 suitably selected in their constituent material, a multi-wavelength light can be emitted containing at least wavelengths in any of ultraviolet to visible light ranges and infrared light range of a 1.3 μm and a 1.5 μm band.

As regards features of an LD according to the third aspect of the present invention, the LD of the invention, which is designed to emit light inductively, due to light emissions from multiple quantum levels of the non-uniform quantum dot structure, has a broad range of emission wavelengths. Thus, an LD using a semiconductor multi-layered structure having non-uniform quantum dots in accordance with the present invention, which has a broad range of emission light wavelengths, can be implemented into small-sized and light-weighted LD applied devices.

Next, a semiconductor light amplifier using a semiconductor multi-layered structure having non-uniform quantum dots according to a fourth aspect of the present invention is shown.

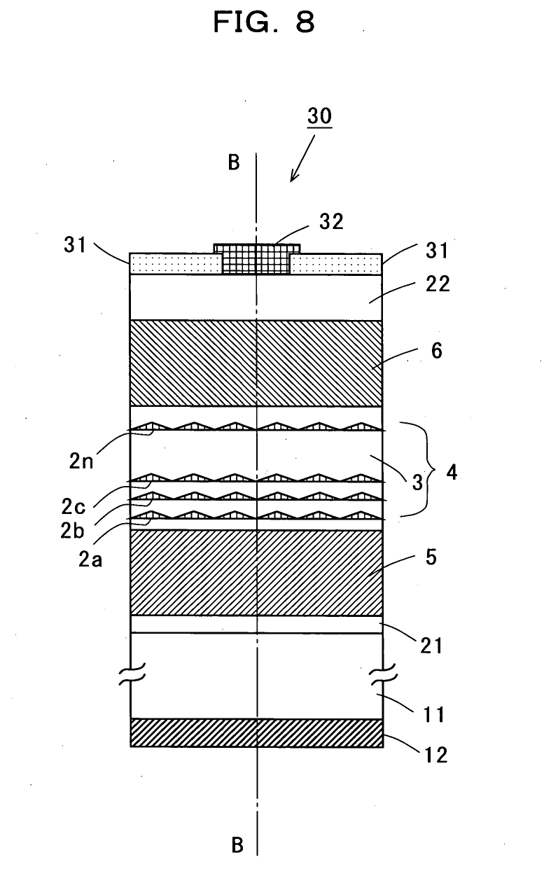

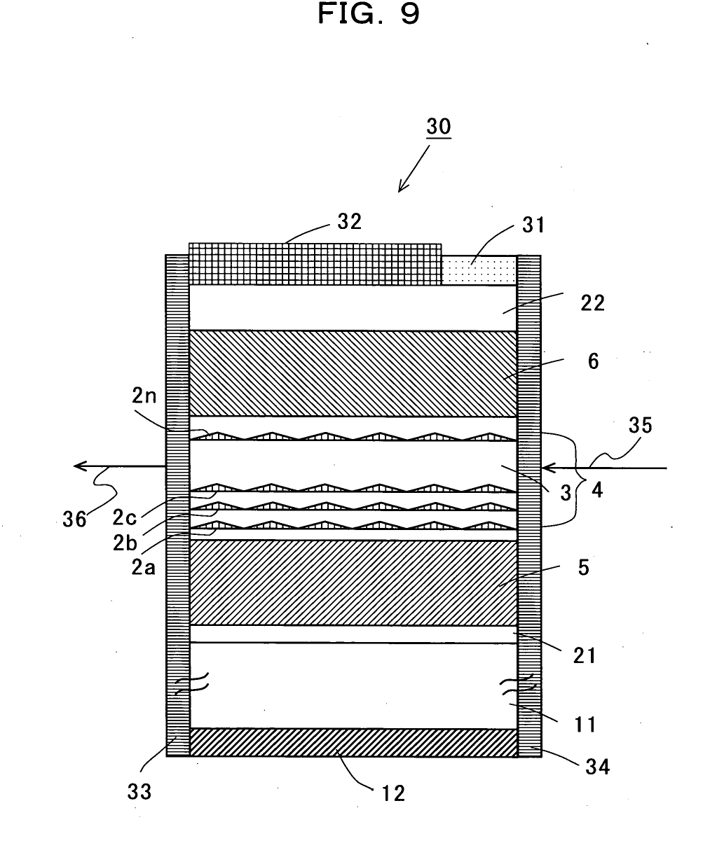

FIG. 8 is a diagrammatic cross sectional view of such a semiconductor light amplifier using a semiconductor multi-layered structure having non-uniform quantum dots according to the fourth aspect of the present invention. FIG. 9 is a diagrammatic cross sectional view taken along the line B-B in FIG. 8. In the Figures, a semiconductor light amplifier 30 using a semiconductor multi-layered structure having non-uniform quantum dots formed without requiring lattice strain in accordance with the present invention is shown having a multi-layered structure identical to that of the LD 20 shown in FIG. 6. Here, the n-type semiconductor substrate 11, the buffer layer 21 and the p⁺-type semiconductor layer 22 can be formed of an identical semiconductor which is assumed to have a forbidden band Eg1. Then, assuming also that the n-type and p-type clad layers 5 and 6, the semiconductor layer 3 in the active layer and the semiconductor forming the non-uniform quantum dots have forbidden bands Eg2, Eg3 and Eg4, respectively, it may suffice if these forbidden bands have relationship: Eg1>Eg2>Eg3>Eg4.

The semiconductor light amplifier 30 using a semiconductor multi-layered structure having non-uniform quantum dots in accordance with the present invention differs in configuration from the LD 20 in that it is configured not to produce laser oscillations but to operate as an amplifier. As shown in FIG. 9, the p⁺-type semiconductor layer 22 has an electrode 32 formed and seated with an opening formed in an insulating film 31. The electrode 32 is disposed axially to orient obliquely to the optical axis of an incident and an amplified light 35 and 36 in the structure and also to partially lie thereon so that current injection may not bring about laser oscillations. Further, antireflection coatings 33 and 34 are provided on the opposed end faces in the direction of the optical axis so that the incident and amplified lights 35 and 36 may not reflect there. As a result, the Fabry-Perot resonator is not formed here.

A multi-layered structure of the semiconductor light amplifier 30 may be formed, for example, by epitaxially growing a buffer layer 21 of n-type InP with an impurity density of 1×10¹⁷ to 5×10¹⁸ cm⁻³ to a thickness of 0.001 μm to 2 μm, a n-type clad layer 5 of n-type Al_{0.40}Ga_{0.07}In_{0.53}As with an impurity density of 1×10¹⁷ to 5×10¹⁸ cm⁻³ to a thickness of 0.5 μm to 3 μm, an active layer 4 of a non-uniform quantum dot structure to a thickness of 0.1 μm to 3 μm wherein the non-uniform quantum dot structure 2 has one to twenty layers of non-uniform quantum dots of InAs formed without requiring lattice strain in a semiconductor layer 3 of Al_{0.26}Ga_{0.21}In_{0.53}As large in forbidden band, a p-type clad layer 6 of p-type Al_{0.40}Ga_{0.07}In_{0.53}As with an impurity density of 1×10¹⁷ to 5×10¹⁸ cm⁻³ to a thickness of 0.5 μm to 3 μm and a p⁺-type semiconductor layer 22 of p-type InP with an impurity density of 1×10¹⁸ to 5×10¹⁹ cm−3 to a thickness of 0.5 μm to 5 μm, successively on an n-type InP substrate 11 of 250 μm to 500 μm thick and with an impurity density of 1×10¹⁸ to 1×10¹⁹ cm⁻³.

Mention is made of an operation of the semiconductor light amplifier 30 using a semiconductor multi-layered structure having non-uniform quantum dots in accordance with the present invention.

In the semiconductor light amplifier 30 using a semiconductor multi-layered structure having non-uniform quantum dots in accordance with the present invention, a plurality of quantum levels of the non-uniform quantum dot structure formed in the active layer 4 are brought into an excited state by forward current injection. In this state, when a light 35 lower in energy, namely longer in wavelength than lights emitted from the levels of the non-uniform quantum dot structure is incident, the semiconductor light amplifier 30 of the present invention operates as a semiconductor amplifier to amplify the incident light 35 passing through its inside and emit an amplified light 36 into its outside. Then, with the non-uniform quantum dot layers 2 suitably selected in their constituent material, a light amplification can be effected for multiple wavelengths including at least those in any of ultraviolet to visible light ranges and infrared light range of a 1.3 μm and a 1.5 μm band.

Mention is next made of features of a semiconductor light amplifier according to the forth aspect of the present invention as described above.

According to the non-uniform quantum dot structure of the active layer 4 here, the optical gain which its quantum levels permit readily reaches a value that is, for example, 5 to 6 orders of magnitudes higher than that which an Er doped optical fiber of an Er doped fiber optic amplifier used in the current optical information transmission communication permits. Consequently, a semiconductor light amplifier according to the present invention if its length in a direction in which an input light is incident is even as short as 0.1 mm to 1 mm, can enough and readily achieve an amplification which the conventional Er doped optical fiber of about 10 m to 100 m long can barely achieve. Moreover, such a semiconductor light amplifier high in amplification degree can readily be obtained. Thus, a light amplifier smaller in size and lighter in weight than a conventional Er doped fiber optic amplifier can be brought to realization according to a semiconductor light amplifier of the present invention.

Next, in accordance with a fifth aspect of the present invention a method of making a semiconductor device, such as a light emitting diode, a semiconductor laser diode or a semiconductor light amplifier, using a semiconductor multi-layered structure having non-uniform quantum dots in accordance with the present invention is shown. Hereinafter, for the sake of convenience a semiconductor diode, a light emitting diode and a semiconductor light amplifier using a semiconductor multi-layered structure having non-uniform quantum dots will generally be referred to as “semiconductor device”.

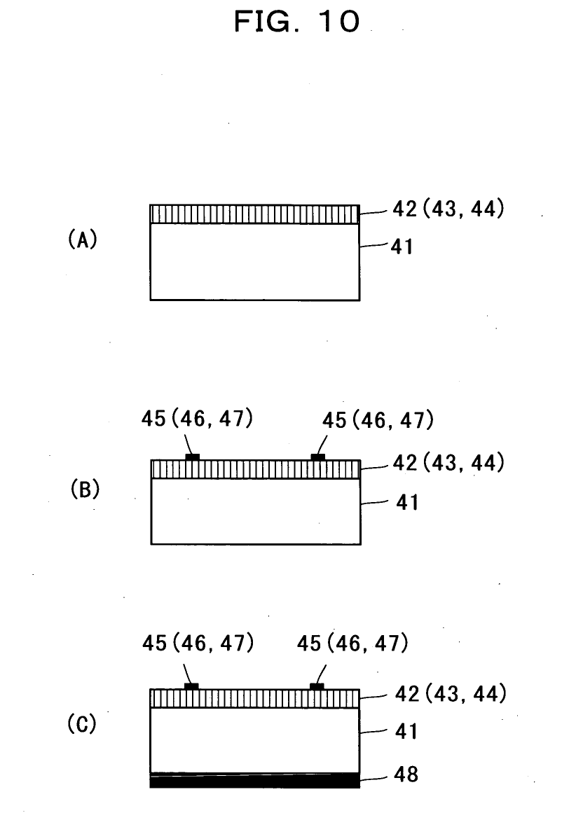

FIG. 10 shows cross sectional views of a semiconductor device illustrating a method of making a semiconductor device according to a fifth aspect of the present invention. As shown in FIG. 10(A), first an operating layer 42, 43 or 44 corresponding to one of those in the LED 15, the LD 20 and the semiconductor light amplifier 30 shown in FIGS. 5, 7 and 9, respectively, is grown on an n-type InP substrate 41 that is <100>oriented plane, using MOCVD process, or a molecular beam epitaxy (MBE) process. In this process step of forming the operating layer 42, 43 or 44, an active layer 4 having a non-uniform quantum dot structure can be formed without requiring lattice strain, by a droplet epitaxial growth process using the MOCVD or molecular beam epitaxy to be described below. The epitaxially grown operating layer has a p⁺-type InP layer as its uppermost layer, and the n-type InP substrate may have a thickness of 0.25 mm to 0.55 mm.

Next, as shown in FIG. 10(B) metal layers constituting p layer ohmic electrodes are formed on the uppermost, p-type InP layer of the operating layer 42 by sputtering or vapor deposition and is then heat-treated to form ohmic electrodes 45 for the LED 15. Here, in the cases of the LD 20 and the semiconductor light amplifier 30, an insulator such as a Si nitride film is deposited on the uppermost layer of the epitaxially grown operating layer by CVD and then has windows formed in which p-layer ohmic electrodes 46 and 47 are formed, respectively.

Next, as shown in FIG. 10(C) a metal layer constituting an ohmic electrode is formed on the rear surface of the n-type InP substrate 41 by sputtering or vapor deposition and is then heat-treated to form an n-layer ohmic electrode 48. Here, in the cases of the LD 20 and the semiconductor light amplifier 30, facilitating cleavage and heat dissipation may require thinning the InP substrate 41 to 100 μm or so in thickness by polishing prior to forming the n layer ohmic electrode.

Next, in the case of the LED 15, cuts are made in a pattern of dice into the body from its front face with a rapidly rotating diamond slicer. The depth of cuts may then be to an extent of one half of the thickness of the n-type InP substrate 41. After such pattern cutting, the body is mesa-etched to remove work strain and then mechanically split along cut surfaces into a plurality of small cube-like bodies. In the case of the LD 20, the body is split by cleaving to form a Fabry-Perot resonator with cleavage surfaces. Then, such surfaces constituting the mirror end faces of the Fabry-Perot resonator may suitably be coated with an insulating film or the like for antidegradation. In the case of the semiconductor light amplifier 30, the body is split by cleaving as in the case of the LD 20 and cleavage surfaces constituting the opposite end faces of the amplifier in the direction of its optical axis are each formed with an anti-reflection coating.

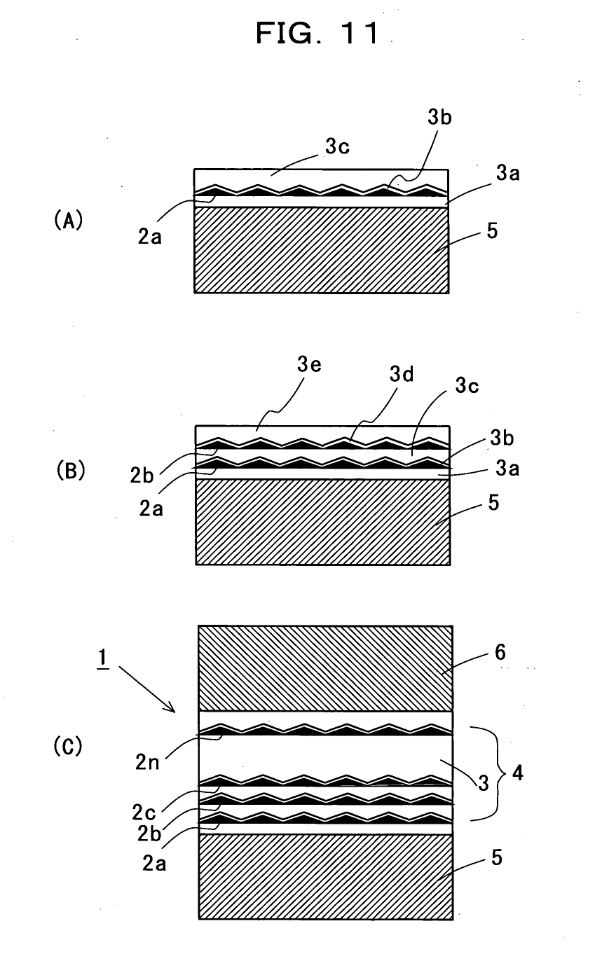

FIG. 11 shows partial cross sectional views of growth layers for illustrating a droplet epitaxial growth process used in the method of making a semiconductor multi-layered structure 1 having non-uniform quantum dots according to the fifth aspect of the present invention. Here, an explanation is made of forming the active layer 4 having a non-uniform quantum dot layer 2 with the assumption that the n- and p-type clad layers 5 and 6 are composed of Al_{0.40}Ga_{0.07}In_{0.53}As, the non-uniform quantum dot layer 2 that can be formed without lattice strain is composed of InAs and the semiconductor layer 3 large in forbidden band is composed of Al_{0.26}Ga_{0.21}In_{0.53}As.

As shown in FIG. 11(A), for example, first the n-type clad layer 5 and an Al_{0.26}Ga_{0.21}In_{0.53}As layer 3a are grown onto an n-type InP substrate having <100> oriented plane (not shown) by using the MOCVD process.

Next, in forming a first layer of the non-uniform quantum dot structure 2 of InAs, first an organometallic gas containing In is simply flown at a selected flow rate for a selected time period to form a large number of In droplets on the Al_{0.26}Ga_{0.21}In_{0.53}As layer 3a. Then, an organometallic gas containing As is simply flown at a selected flow rate for a selected time period to arsenide In droplets, thereby forming quantum dots 19. Here, since a distribution is made for each of both the size of quantum dots in the plane of their growth layer and the thickness of quantum dots in their growth direction, unlike in the conventional S-K growth mechanism the quantum dot layer 2a here is formed as non-uniform and without utilizing lattice strain (see FIG. 11(B)).

Next, on these quantum dots 19 is there grown and deposited an Al_{0.26}Ga_{0.21}In_{0.53}As layer 3b to a thickness of, e. g., 5 to 10 nm. During this growth, constituent elements or atoms of the compound semiconductors of the clad layer 5 and the Al_{0.26}Ga_{0.21}In_{0.53}As layer 3b melt back and diffuse across the layers and as a result the quantum dots 19 come to contain besides InAs, and incorporate, Ga from, e. g., the clad layer 5 and is thereby recomposed into InₓGa_{y}As (where x+y=1). Moreover, this composition changes in the direction in which the InAs droplets grow, namely in their thickness direction, the feature further contributing to rendering the formed quantum dots uneven and non-uniform. Thus, it is the droplet epitaxial growth process that is used to form the quantum dots here. A further Al_{0.26}Ga_{0.21}In_{0.53}As layer 3c is then grown to a desired thickness to flatten above the quantum dot layer 2a.

And, as shown in FIG. 11(B), in addition to the quantum dot layer 2a are formed a layer of In droplets and an Al_{0.26}Ga_{0.21}In_{0.53}As layer 3d as described above in connection with FIG. 11(A) and on the latter layer is deposited an Al_{0.26}Ga_{0.21}In_{0.53}As layer 3e for flattening. These steps are repeated to form a plurality of non-uniform quantum dot structural layers as desired.

Thereafter, as shown in FIG. 11(C), forming a non-uniform quantum dot structural layer 2n is followed by depositing the p-type clad layer 6 by way of MOCVD. In this manner, the semiconductor multi-layered structure 1 having non-uniform quantum dots can be formed.

Mention is next made of advantageous features of a method of making a semiconductor device using a semiconductor multi-layered structure having non-uniform quantum dots in accordance with the present invention. A method of making an LED using a semiconductor multi-layered structure having non-uniform quantum dots in accordance with the present invention allows a light emitting diode broad in range of emission wavelengths to be manufactured with ease and without necessitating additional process steps to the conventional method of making light emitting diodes. Also, a method of making an LD using a semiconductor multi-layered structure having non-uniform quantum dots in accordance with the present invention allows an LD having a multi of emission wavelengths to be manufactured without requiring a resonator structure such as with a diffraction grating and hence in a reduced number of process steps and thus allows such LDs to be manufactured higher in reliability, better in yield and more easily than the conventional method of making LDs. Also, a method of making a semiconductor light amplifier using a semiconductor multi-layered structure having non-uniform quantum dots in accordance with the present invention allows a semiconductor light amplifier broad in range of amplifiable wavelengths to be manufactured without necessitating additional process steps to, and such semiconductor light amplifiers higher in yield than, the conventional method of making semiconductor light amplifiers.

Mention is next made of an MOCVD process when used in the method of making a semiconductor device using a semiconductor multi-layered structure having non-uniform quantum dots in accordance with the present invention.

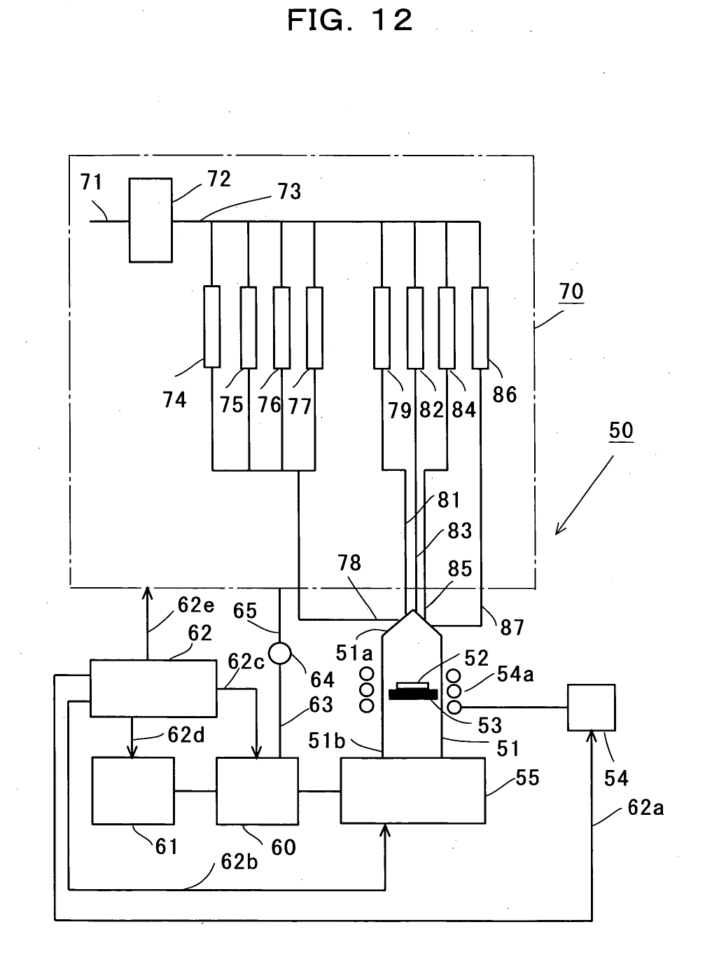

FIG. 12 is a diagram illustrating the makeup of an MOCVD apparatus for use in the method of making a semiconductor device according to a sixth aspect of the present invention. An MOCVD apparatus 50 includes a silica reaction tube 51 in which is disposed a susceptor 53 made of carbon for holding a substrate 52. The silica reaction tube 51 is exteriorly wound with a heating coil 54a for a high frequency induction heater 54 included to heat the susceptor. The silica reaction tube 51 has one end 51a to which is connected a gas supply system 70 for feeding the tube with source gases and hydrogen as a carrier gas. The substrate 52 is adapted to be inserted from a specimen loading chamber 55 connected through the other end 51b of the silica reaction tube 51.

The silica reaction tube 51 and the specimen loading chamber 55 are adapted to be evacuated by a vacuum pumping unit 60 and thereafter to be returned to a normal or reduced pressure for crystal growth. Further, the above-mentioned gas supply system has a gas piping suitably evacuated by the vacuum pumping unit 60. The gas piping in its vacuum drawing system comprises vacuum pipes 63 and 65 and a valve 64. The gases fed into the silica reaction tube 51 are expelled via the vacuum pumping unit 60 and treated through a waste gas processing unit 61.

Further included is a controller 62 adapted to issue control signals 62a, 62b, 62c, 62d and 62e for controlling operations of the high frequency induction heater 54, the specimen loading chamber 55, the vacuum pumping unit 60, the waste gas processing unit 61 and the gas supply system 70, respectively.

In the gas supply system 70, the hydrogen gas source 71 is purified by a hydrogen purifier 72. In a vessel supplied with organometallic gases containing constituent elements or atoms of InP, AlₓGa_{y}In_{z}As (where x+y+z=1) and InAs, respectively, and also impurities, purified hydrogen gas 73 is mixed with each of these organometallic gases and also with a gas containing impurities, respectively, and mixtures are fed into the silica reaction tube 51.

Here, organometallic compounds as source gases of Al, Ga and In as group III elements, As and P as group V elements and Zn as a p-type impurity element may use TMAl (trimethyl aluminum: Al(CH₃)₃), TEGa (triethyl gallium: Ga(C₂H₅)₃), TMIn (trimethyl indium: In(CH₃)₃), TBAs (tertiary butyl arsine: t-C₄H₉AsH₂), TBP (tertiary butyl phosphine: t-C₄H₉PH₂) and DEZn (diethyl zinc: Zn(C₂H₅)₂), respectively.

Gases whose flow rates are controlled by respective gas control units 74, 75, 76 and 77 for TMAl, TEGa, TMIn and DEZn are fed via a gas supply line 78 into the silica reaction tube 51 at its inlet end 51a. TBAs has its flow rate controlled by a TBAs gas control unit 82 and is fed via a supply line 83 into the silica reaction tube at its inlet end 51a. TBP has its flow rate controlled by a TBP gas control unit 79 and is fed via a supply line 81 into the silica reaction tube at its inlet end 51a. S as an n-type impurity element has its flow rate controlled by a H₂S gas control unit 84 and is fed via a supply line 85 into the silica reaction tube at its inlet end 51a. Purified hydrogen gas 73 has its flow rate controlled by a hydrogen gas control unit 86 and is fed via a supply line 87 into the silica reaction tube at its inlet end 51a.

Here, each of the organometallic gas control units 74 to 77, 79 and 82 comprises a vessel, a temperature regulator for maintaining the temperature of the vessel constant to maintain the vapor pressure of the source gas constant, a mass flow controller for controlling the respective rates of flow of hydrogen gas and the organometallic gas bubbled therewith, and a valve.

The H₂S gas control unit 84 comprises a bomb filled with purified gas, a pressure regulator, a flow rate regulating mass flow controller and a valve. The hydrogen gas control unit 86 comprises a mass flow controller to control flow rate and a valve. These gas control units (74 to 77, 79, 82, 84, and 86) are each designed to respond to the control signal 62e from the controller 62 to control supply, stop and flow of the gas.

Mention is next made of the epitaxial growth by the MOCVD apparatus 50 for a semiconductor multi-layered structure having non-uniform quantum dots and a semiconductor device made thereof. An InP substrate 52 cleaned is introduced from the specimen loading chamber 55 into the silica reaction tube 51 and disposed on the susceptor 53 and the silica reaction tube 51 is evacuated to a selected degree of vacuum. Then, purified hydrogen gas 73 as carrier gas is passed to flow in the silica reaction tube 51 and the InP substrate 52 is heated by the high frequency induction heater 54 to a growth temperature of 500 to 650° C. Here, when the InP substrate 52 reaches a temperature of 300° C., TMP is initiated to flow to prevent P from detaching from the InP substrate 52.

Then, successive flows of selected gases from the gas control units (74 to 77, 79, 82, 84, and 86) cause InP, InAs, Al_{0.26}Ga_{0.21}In_{0.53}As and Al_{0.40}Ga_{0.07}In_{0.53}As layers to crystallographically grow one after another. Here, TMIn and TBP may be used as the source gases for InP growth, and further, H₂S may be used as an impurity of n-type InP. Also, a flow of DEZn may grow p-type InP. Further, TMAl, TEGa, TMIn and TBAs may be used as the source gases to grow Al_{0.26}Ga_{0.21}In_{0.53}As and Al_{0.40}Ga_{0.07}In_{0.53}As. For growing n-type and p-type Al_{0.26}Ga_{0.21}In_{0.53}As and Al_{0.40}Ga_{0.07}In_{0.53}As layers, H₂S and DEZn may be added to them, respectively.

Further, a desired number of non-uniform quantum dot structural layers 2 may be formed by droplet epitaxy as described in connection with FIG. 11. Then, controlling the heating temperature of the InP substrate and the flow rates of organometallic gases and H₂S gas allows layers of such as InP, InAs, Al_{0.26}Ga_{0.21}In_{0.53}As and Al_{0.40}Ga_{0.07}In_{0.53}As layers to grow epitaxially on the InP substrate. In this manner, epitaxial growth layers of a semiconductor multi-layered structure having non-uniform quantum dots of the present invention and of a semiconductor layer using the structure can be fabricated using MOCVD.

When MOCVD is used to form on an InP substrate a non-uniform quantum dot structure of InAs as a semiconductor multi-layered structure having non-uniform quantum dots in accordance with the present invention, crystal growth at a temperature of 500° C. to 560° C. allows forming a non-uniform quantum dot structure without requiring lattice strain wherein the quantum dots have an average diameter in growth plane of 40 nm, a height of 7 nm and a density in plane of 3×10¹⁰ cm⁻². Here, the dimensions and density in plane of quantum dots are measured by an AFM (atomic force microscope). According to the present invention, it is possible to form a non-uniform quantum dot structure in this manner and to form a multiplicity of quantum levels due to such a non-uniform quantum dot structure efficiently.

Mention is next made of specific examples of the invention.

### EXAMPLE 1

Firstly, a specific example is given of the semiconductor multi-layered structure 1 using a non-uniform quantum dot structure that can be formed without lattice strain, which was fabricated using MOCVD and droplet epitaxial growth process. For MOCVD, use was made of an apparatus as described above in connection with FIG. 12.

After cleaning with an organic solvent and etching with an acidic etching liquid, an n-type InP substrate 52 having a thickness of 350 μm and an electron concentration of 4×10¹⁸ cm⁻³ and with a (100) plane was introduced from the specimen loading chamber 55 into the silica reaction tube 51 and set in position on the susceptor 53 therein. The silica reaction tube 51 was then evacuated to vacuum at a selected pressure by the vacuum pumping unit 60, followed by passing purified hydrogen gas 73 to flow through the silica reaction tube 51 which was then maintained at a pressure of 76 Torr.

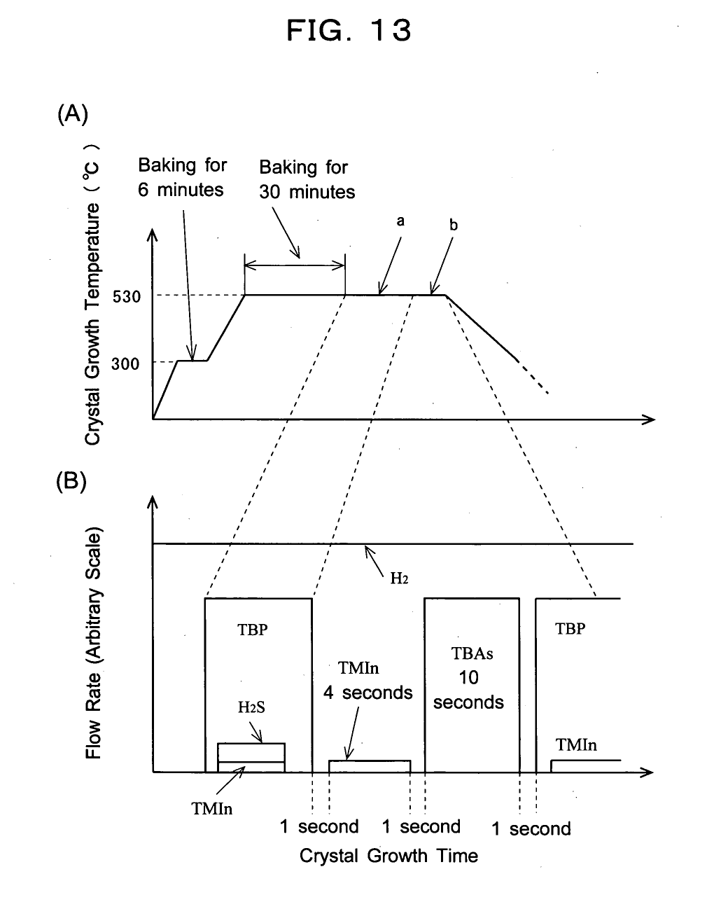

FIG. 13 shows graphs illustrating a relationship between the growth temperature and the gas flow rate during crystal growth for a semiconductor multi-layered structure 1′ with a non-uniform quantum dot structure. The ordinate axis of the graph in FIG. 13(A) represents the crystal growth temperature (° C.) while the ordinate axis of the graph in FIG. 13(B) represents the gas supply flow rate in arbitrary scale. The abscissa axes in both graphs represent the crystal growth time. The hydrogen gas has a flow rate of 4 slm and is left flowing constantly. Here, slm stands for “standard liter per minute” represented by L (liter=1000 cm³)/minute and represents a unit of flow rate calculated at a temperature of 0° C. and at a pressure of 1013 hPa. To form a non-uniform quantum dot structure 1′, a buffer layer 7 of InP with an electron concentration of 4×10¹⁸ cm⁻³ was formed at a growth temperature of 530° C. from TMIn, TBP and H₂S to a growth thickness of 100 nm on the n-type InP substrate 11 of an electron concentration of 4×10¹⁸ cm⁻³ (see FIG. 13(A), a). Then, TMIn, TBP and H₂S had supply flow rates of 1.68×10⁻⁷ mol/second, 3.38×10⁻⁶ mol/second and 1.67×10⁻⁹ mol/second, respectively.

Then, TMIn and H₂S ceased to be supplied and TBP was initiated to flow and then ceased to be supplied. After a lapse of 1 second, a non-uniform quantum dot structure began to be formed by first passing TMIn to flow for 4 seconds to form In droplets. Then, TMIn ceased to be supplied and after a lapse of 1 second TBAs was passed to flow for 10 seconds and then ceased to flow.

Subsequently, after a lapse of 1 second, at first TBP was passed to flow and then TMIn was supplied to grow an InP layer to a thickness of 10 nm, thereby forming a non-uniform quantum dot structure 2a (see FIG. 13(A), b). Then, TMIn, TBP and TBAs had supply flow rates of 1.68×10⁻⁷ mol/second, 3.38×10⁻⁶ mol/second and 3.38×10⁻⁶ mol/second, respectively.

After the growth, TMIn ceased to be supplied and only TMP was allowed to flow while slowly cooling the InP substrate to form a semiconductor multi-layered structure 1′ having a non-uniform quantum dot structure.

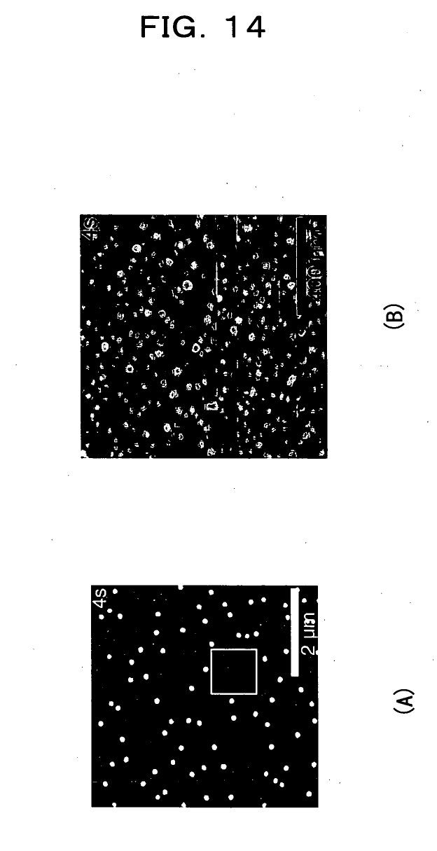

FIG. 14 shows a surface observed with an atomic force microscope, of a structure of non-uniform quantum dots grown by a droplet epitaxial growth process wherein a surface area enclosed with a square frame shown in FIG. 14(A) has an area of 1 μm×1 μm in size, which is shown as enlarged in FIG. 14(B), from which a structure having quantum dots different in size, namely non-uniform, is observed.

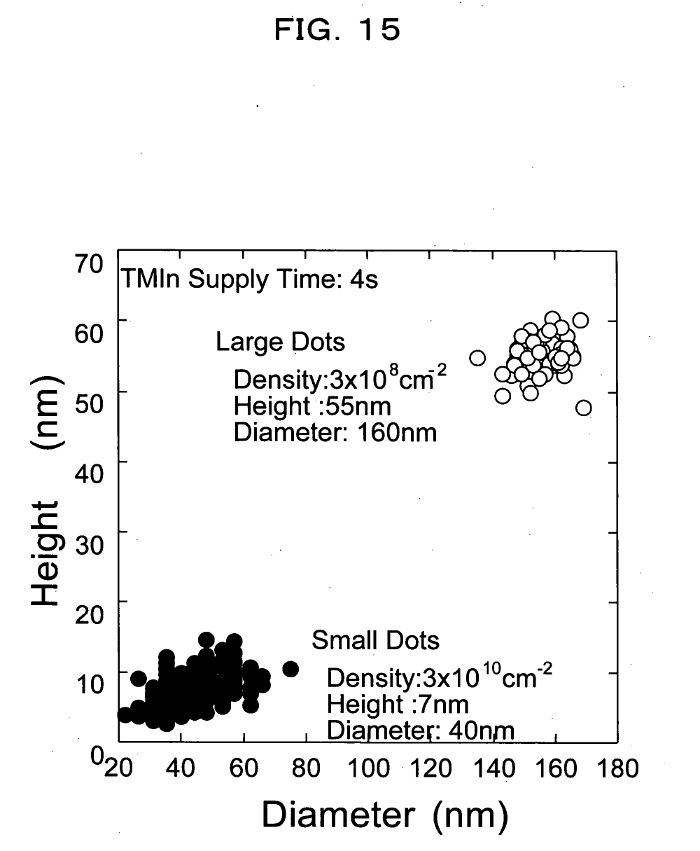

Mention is next made of the size of a non-uniform quantum dot structure found from observations with an atomic force microscope. FIG. 15 is a graph illustrating sizes of non-uniform quantum dots formed by the droplet epitaxial growth process. The graph has its ordinate axis representing the thicknesses (in nm) of quantum dots in their growth direction and its abscissa axis representing the diameters (in nm) of quantum dots in their growth plane. In a non-uniform quantum dot structure, it is seen that there are smaller and larger quantum dots. Here, densities in plane of small and large quantum dots were found to be 3×10¹⁰ cm⁻² and 3×10⁸ cm⁻², respectively.

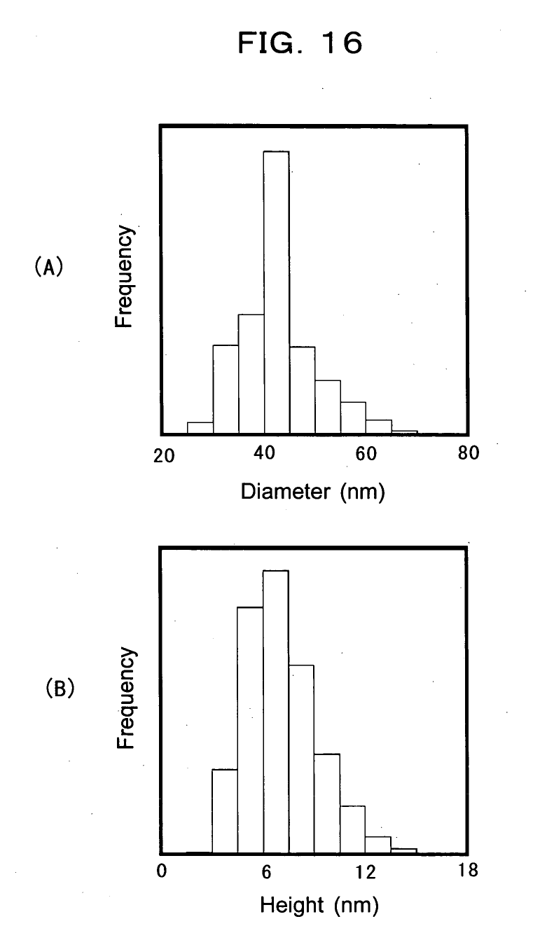

FIG. 16 shows graphs illustrating distributions of the diameters and heights of small dots of non-uniform quantum dots formed by the droplet epitaxial growth process wherein FIGS. 16(A) and 16(B) show such diameter and height distributions, respectively. Each of the graphs shown has its ordinate axis representing the frequency. The small dots distribute in diameter from 20 nm to 75 nm, having an average diameter of 40 nm, and also distribute in height between 2 nm and 16 nm, having an average height of 7 nm. On the other hand, it was found that the large dots distributed in diameter from 135 nm to 170 nm, having an average diameter of 160 nm, and also distributed in height between 47 nm and 60 nm, having an average height of 55 nm. While these are the values obtained when the time period in which the TMIn gas is supplied to initially form the In droplets was set to 4 seconds for non-uniform quantum dots to be formed by droplet epitaxial growth process using said MOCVD apparatus, and about 1 second to 8 seconds turned out to give the food non-uniform quantum dot structure.

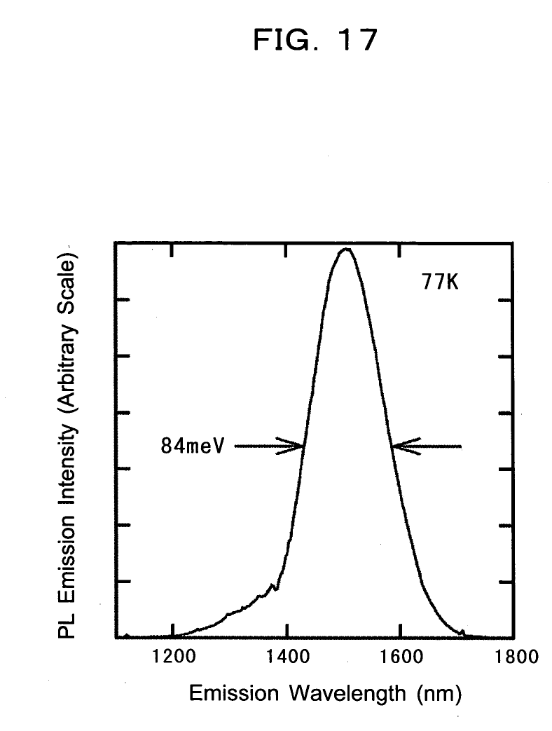

FIG. 17 is a graph illustrating luminous emission intensity by photo luminescence of a semiconductor multi-layered structure having non-uniform quantum dots according to the present invention. The graph has its ordinate axis representing the PL (photo luminescence) emission intensity (in arbitrary scale) and its abscissa axis representing the emission wavelength (in nm). Measurements were made upon irradiating the semiconductor multi-layered structure 1′ having the non-uniform quantum dot structure with an Ar laser light (with a wavelength of 514.5 nm) from an excitation light source of 400 mW. The semiconductor multi-layered structure 1′ having the non-uniform quantum dot structure had a temperature of 77° K. The light emission from the semiconductor multi-layered structure 1′ with the non-uniform quantum dot structure has passed a grating spectroscope, and was detected by a high sensitivity Ge-pin photo diode. The light emission from the semiconductor multi-layered structure 1′ having the non-uniform quantum dot structure was found to possess a broad emission spectrum of a breadth from 1200 nm to 1700 nm. It is also shown that its half-value breadth is 84 meV. It is thus seen that light emission of a band of 1.2 μm to 1.7 μm is obtained from the semiconductor multi-layered structure 1′ having non-uniform quantum dots in accordance with the present invention.

### EXAMPLE 2

A specific example is given of crystal growth for an LED 15 using a semiconductor multi-layered structure having non-uniform quantum dots as shown in FIG. 5. Here, use was made of the same MO CVD apparatus shown in and described in connection with FIG. 12.

The multi-layered structure of an LED 15 was formed by depositing an n-type semiconductor layer 7 of InP with an impurity density of 1×10¹⁷ to 5×10¹⁸ cm⁻³ to a thickness of 0.001 μm to 2 μm, an active layer 4 having non-uniform quantum dots formed without requiring lattice strain to a thickness of 0.1 μm to 3 μm, and a p-type semiconductor layer 8 of p-type InP with an impurity density of 1×10¹⁸ to 5×10¹⁹ cm⁻³ to a thickness of 0.5 μm to 5 μm, successively on an n-type InP substrate 11 with an impurity density of 1×10¹⁸ to 1×10¹⁹ cm⁻³ and having a thickness of 250 μm to 500 μm. Further, an n layer and p layer ohmic electrode 12 and 13 were formed using AuGe and AuZn alloys, respectively.

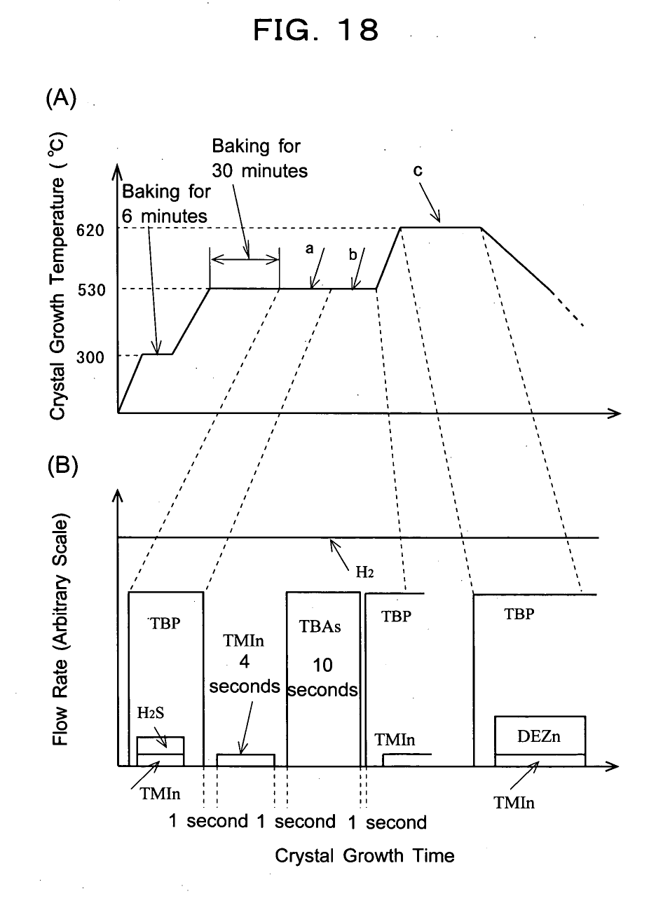

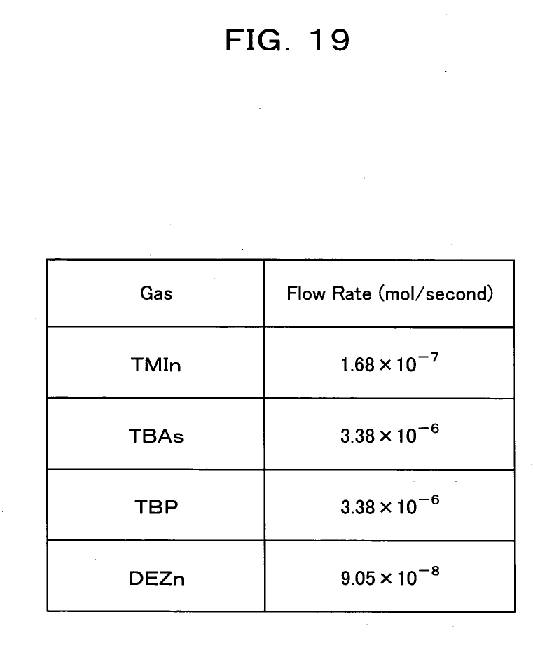

FIGS. 18 and 19 show graphs illustrating a relationship between the growth temperature and the gas flow rate during crystal growth for an LED using a semiconductor multi-layered structure having non-uniform quantum dots wherein the graph in FIG. 18(A) has its ordinate axis representing the crystal growth temperature (in ° C.) while the graph in FIG. 18(B) has its ordinate axis representing the gas supply flow rate in an arbitrary scale. The graphs have their abscissa axes representing the crystal growth time. FIG. 19 is a table giving specific values for the flow rate of gas supply for successive layers grown in the structure. The flow rate is shown with a unit of mol/second. Here, hydrogen gas has a flow rate of 4 slm as left flowing constantly.

In forming the LED 15 here, a p-type semiconductor layer 8 was grown on a non-uniform quantum dot structure prepared using a process step as in Example 1. After the non-uniform quantum dot structure was grown in that process step, TMIn ceased to be supplied and TBP was left flowing while raising the temperature of the InP substrate from 530° C. to 620° C.

Next, by first passing TBP to flow and then feeding TMIn and DEZn as a gas containing an p-type impurity, the p-type semiconductor layer 8 of InP having a positive hole concentration of 4×10¹⁸ cm⁻³ was grown to a thickness of 2 μm (see c in FIG. 18(A)). Then, TMIn, TBP and DEZn had supply flow rates of 1.68×10⁻⁷ mol/second, 3.38×10⁻⁶ mol/second and 9.05×10⁻⁸ mol/second, respectively.

Then, supply of TMIn and DEZn was terminated and only TBP was continued to flow while slowly cooling the InP substrate whereupon to finish forming the epitaxial growth layer of the LED 15. Here, the specific values of the thicknesses of the growth layers and of the impurity densities given above are an example only, and it should also be noted that any other semiconductor device, such as an photo diode, LD or semiconductor light amplifier, using a semiconductor multi-layered structure 1 having non-uniform quantum dots can likewise be made on epitaxially growing an operating layer by MOCVD and droplet epitaxial growth processes.

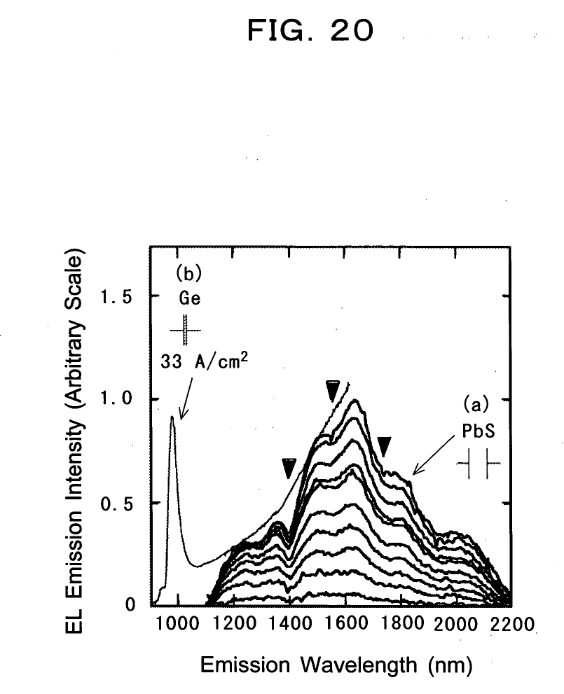

Mention is next made of optical properties of an LED having a semiconductor multi-layered structure having non-uniform quantum dots in accordance with the present invention. FIG. 20 is a graph illustrating emission spectra for an LED using a semiconductor multi-layered structure having non-uniform quantum dots according to the present invention when it is forward injected at a room temperature. In the Figure, the graph shown has its abscissa axis along which is plotted the emission wavelength in nm and its ordinate axis along which the emission intensity is plotted, wherein the symbol (— | | —) as the width of an emission wavelength indicates its resolution. Light emissions of the LED 15 according to the present invention being broad in range of wavelengths, those in a region of short wavelengths were measured by a Ge-pin photo diode and those in a region of longer wavelengths by a PbS photo diode. The emission spectrum shown is of the pulse-driven LED 15 when it was driven by forward current pulses with a current density of 10 A/cm² to 110 A/cm². The pulses then had a pulse width of 10 ms and a repetition rate of 50 Hz.

As shown, it is seen that the LED 15 is broad in emission wavelength, ranging from 0.9 μm to 2.2 μm. It is also seen that this emission spectrum stands held when the forward current is varied from 10 A/cm² to 110 A/cm². Drops in emission intensity indicated by inverted triangles (▾) in the Figure are due to absorption by air. Noting that these losses were not compensated for, it is seen that in the absence of such absorption by air the light intensity actually becomes even stronger. Although 0.9 μm as the emission wavelength of InP is found included in the emission wavelengths of the LED 15, its intensity is seen to be much weaker than of those of 1.2 μm and 1.8 μm, and its half-value width much narrower as well.

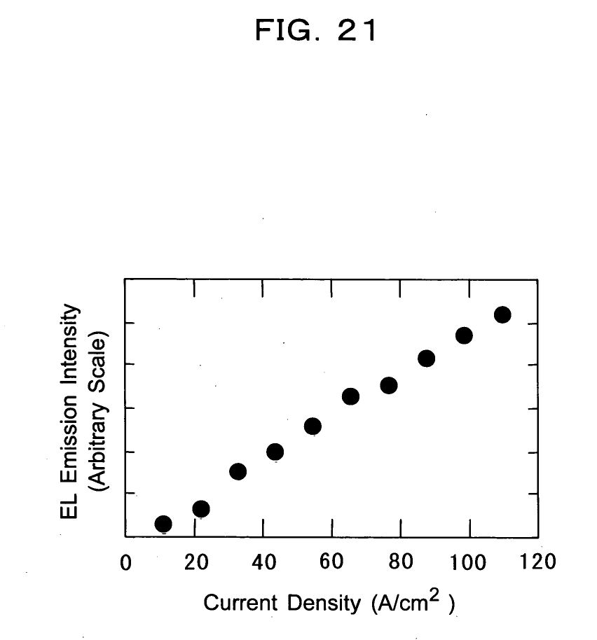

FIG. 21 is a graph illustrating an IL characteristic as a relationship between the electric current and the intensity of emission (EL emission intensity) by current injection for the LED 15 using a semiconductor multi-layered structure having non-uniform quantum dots according to the present invention. The graph shown has its abscissa axis representing the current density (in A/cm²) applied to the LED and its ordinate axis representing the EL emission intensity (in an arbitrary scale). In a region in which the current density is generally from 10 A/cm² to 100 A/cm², the emission intensity is seen to increase linearly with respect to the injected current density, giving rise to good emission characteristics. Then, since smaller quantum dots are approximately 100 times as greater in in-plane density as larger quantum dots as mentioned in Example 1 above, the emission center here is seen to be based on the smaller non-uniform quantum dots. Thus, indeed, as a result of forward current injection into an LED using a semiconductor multi-layered structure having non-uniform quantum dots in accordance with the present invention, light emission broad in wave range, strong and at room temperature, which is based on a non-uniform quantum dot structure, has been observed first in the world.

### EXAMPLE 3

Mention is next made of another specific example of the semiconductor multi-layered structure using a non-uniform quantum dot structure which is made using MOCVD and droplet epitaxial growth processes. Here, use is made again of a MOCVD apparatus as shown in and described in connection with FIG. 12.

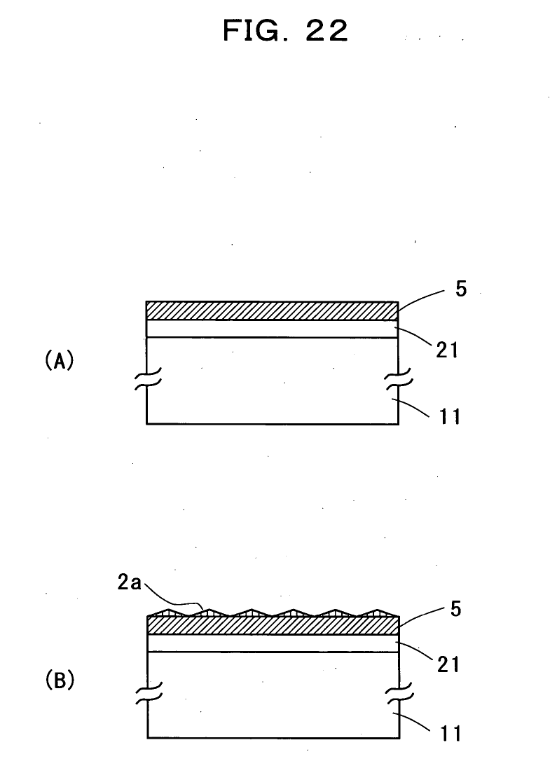

FIG. 22 shows cross sectional views illustrating process steps of making a semiconductor multi-layered structure using a non-uniform quantum dot structure. First, as shown in FIG. 22(a) a buffer layer 21 of InP to a thickness of 100 nm and a clad layer 5 as a layer of In_{0.59}Ga_{0.41}As_{0.89}P_{0.11} were epitaxially grown at a temperature of 620° C. by the MOCVD process and formed successively, on an n-type InP substrate 11 of 350 μm thick, with 4×10¹⁸ cm⁻³, having a (100) plane and doped with S (sulfur).

Next, using the droplet epitaxial process as in Example 1 above, a single, non-uniform quantum dot layer 2a of InAs was formed at a temperature of 530° C. Where necessary, another clad layer 5 (not shown) may then be grown epitaxially by MOCVD at a temperature 620° C. In this manner, performing the droplet epitaxial growth at 530° C. and possibly also the epitaxial growth of the further clad layer 5 at 620° C. can easily optimize the crystal quality of each layer formed.

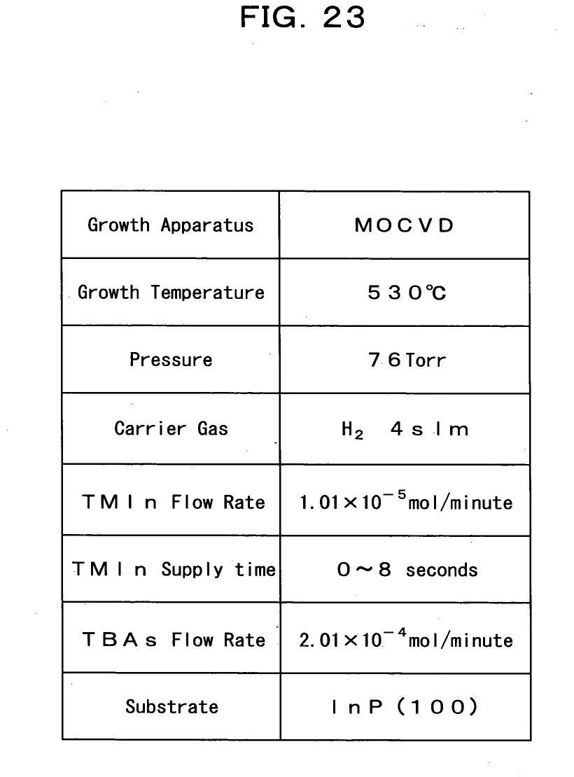

FIG. 23 is a table illustrating growth conditions under which the non-uniform quantum dot layer of Example 3 is formed by the droplet epitaxial growth process. The growth apparatus had a pressure of 76 Torr and hydrogen gas as carrier gas was constantly passed to flow at a flow rate of 4 slm. Also, TMIn and TBAs were supplied at rates of 1.01×10⁻⁵ mol/minute and 2.01×10⁻⁴ mol/minute, respectively. Further, TMIn was supplied for a time period of 0 to 8 seconds to form In droplets. Quantum dots formed into a semiconductor multi-layered structure 1 using a non-uniform quantum dot structure made in this manner were observed by an atomic force microscope.

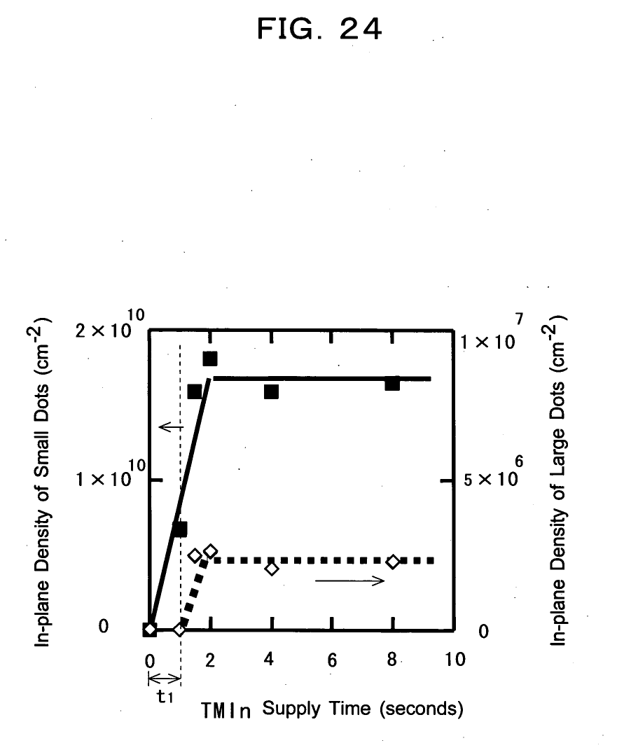

FIG. 24 is a graph illustrating a relationship between the TMIn supply time and the in-plane density of non-uniform quantum dots in the structure of Example 3. The graph shown has its abscissa axis representing the TMIn supply time (in second) and its ordinate axis representing the in-plane density (in cm⁻²) of non-uniform quantum dots. In the graph, the in-plane density of smaller dots is indicated by the solid line and that of larger dots by the dotted line.

As in Example 1, it is seen that both smaller and larger dots are formed. The in-plane density of smaller dots increases linearly with the increase of TMIn supply time from 0 to 2 seconds, reaching 1.7×10¹⁰ cm⁻². If the TMIn supply time runs from 2 to 8 seconds, the in-plane density of smaller dots, albeit with some small variations, is seen to remain saturated at 1.7×10 cm⁻². Increasing the TMIn supply time further there does not increase the in-plane density of smaller dots any longer. This phenomenon is referred to herein as “auto-terminating” mechanism in making non-uniform quantum dots by droplet epitaxial growth process. By utilizing the time period before this auto-terminating mechanism begins to work, it is possible to make quantum dots which when formed do not require lattice strain. So made, small quantum dots when their planar density became the maximum had an average diameter of 55 nm and a height of 5 nm. On the other hand, larger dots were not formed when the TMIn supply ran less than 1 second, and their planar density increased linearly when it ran from 1 to 2 seconds, reaching 2.5×10⁶ cm⁻². If the TMIn supply time is run from 2 to 8 seconds, the in-plane density of larger dots is seen to remain saturated as is that of smaller dots, at 2.5×10⁶ cm⁻². Since larger dots begin to be formed with a time delay of about 1 second after smaller dots begin to be formed, it is possible to form only smaller dots by performing the droplet epitaxial growth in this delay time (t₁) as shown. To increase the planar density of quantum dots in an LD or semiconductor light amplifier, the values given above of them for the one layer may be used to increase the number of such layers of non-uniform quantum dots to an extent that a desired planar density is attained.

### EXAMPLE 4

Mention is next made of another specific example of the LED using a semiconductor multi-layered structure having non-uniform quantum dots. Here, use is made again of a MOCVD apparatus as shown in and described in connection with FIG. 12.

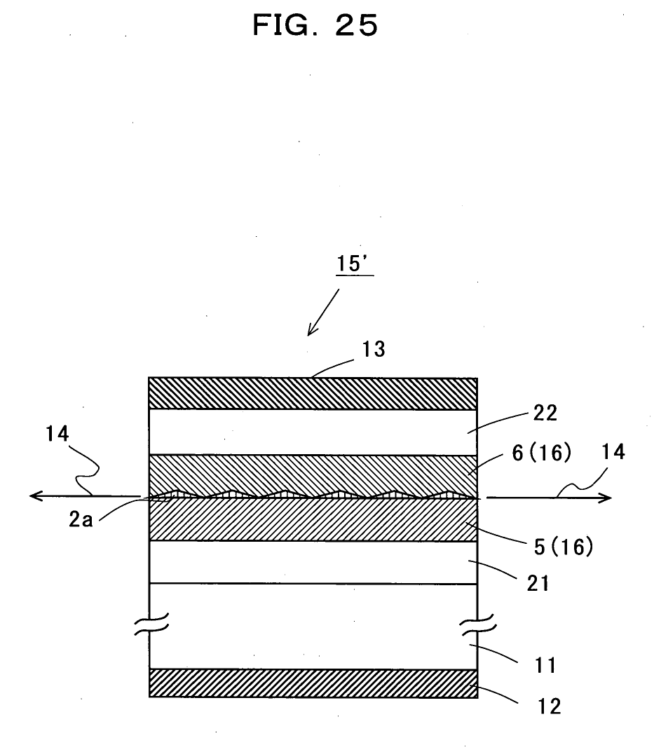

FIG. 25 is a cross sectional view of an LED using a semiconductor multi-layered structure having non-uniform quantum dots according to this Example of the present invention. As shown, a LED 15′ using a semiconductor multi-layered structure having non-uniform quantum dots in accordance with the present invention is structured to comprise an n-type semiconductor substrate 11 and a buffer layer 21 deposited thereon, and an n-type clad layer 5, a single layer 2a of non-uniform quantum dots formed without requiring lattice strain, a p-type clad layer 6 and a p⁺-type semiconductor layer 22 which are successively deposited on the buffer layer 21. The n- and p-type clad layers 5 and 6 may desirably be each an undoped clad layer 16. And, the n-type semiconductor substrate 11 and the p⁺-type semiconductor layer 22 are formed with an n-layer and a p-layer ohmic electrode 12 and 14, respectively. The structure desired of the LED 15′ shown in FIG. 25 is that which adds and further deposits the undoped clad layers 16 and the p-type InP layer 22 to the semiconductor multi-layered structure 1 having non-uniform quantum dots described in Example 3. This structure also corresponds to that of the LED 15 shown in FIG. 5 except that only one layer of non-uniform quantum dots is included in the active layer 4 having a non-uniform quantum dot structure.

The multi-layered structure of the LED 15 includes a buffer layer 21 of InP to a thickness of 100 nm and an n-type clad layer 5 of In_{0.59}Ga_{0.41}As_{0.89}P_{0.11} to a thickness of 100 nm, which were epitaxially grown successively on an n-type InP substrate 11 of 350 μm thick, with an electron density of 4×10¹⁸ cm⁻³, having a (100) plane and doped with S (sulfur) at a temperature of 620° C. by MOCVD.

Next, using the droplet epitaxial growth process as in Example 3 above, a single layer 2a of non-uniform quantum dots of InAs was formed at a temperature of 530° C. Subsequently, using the MOCVD process, a p-type clad layer 6 of In_{0.59}Ga_{0.41}As_{0.89}P_{0.11} was grown at a growth temperature of 620° C. on the non-uniform quantum dot layer 2a to a thickness of 100 nm to flatten above the latter. Further, the p-type InP layer 22 was grown epitaxially to a thickness of 100 nm, and the n-layer and p-layer ohmic electrodes 12 and 13 were formed using AuGe and AuZn alloy, respectively.

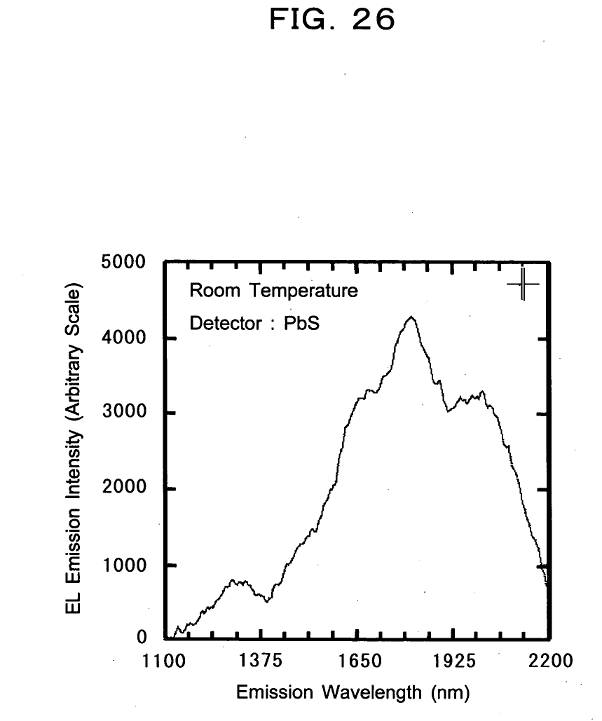

Mention is next made of optical properties of the LED 15′ using a semiconductor multi-layered structure having non-uniform quantum dots in accordance with the present invention. FIG. 26 is a graph illustrating an emission spectrum for the LED 15′ using a semiconductor multi-layered structure having non-uniform quantum dots according to the present invention when the structure is forward injected at room temperature. In the Figure, the graph shown has its abscissa axis along which is plotted the emission wavelength (in nm) and its ordinate axis along which the emission intensity is plotted, wherein the symbol (— | | —) as the width of an emission wavelength indicates its resolution. The detector used in the measurement was a PbS photo diode. The emission spectrum shown is of the LED 15′ when it was pulse-driven by forward current of 500 mA. The LED 15′ having an area generally of 2 mm×2 mm, the current density is about 100 A/cm². The pulses then had a pulse width of 10 ms and a repetition rate of 50 Hz.

It is seen that EL light emission from the semiconductor crystal with the semiconductor multi-layered structure 1 having non-uniform quantum dots has an emission spectrum of a broad band from 1.1 μm to 2.2 μm, centering on 1.8 μm. In this case, the planar density of smaller quantum dots being about 4 orders of magnitudes higher than that of larger quantum dots as mentioned in Example 3, the emission center here is seen to be based on smaller non-uniform quantum dots. It is thus shown that light emission of 1.1 μm to 2.2 μm can be obtained from a LED 15′ with the semiconductor multi-layered structure having non-uniform quantum dots in accordance with the present invention.

### EXAMPLE 5

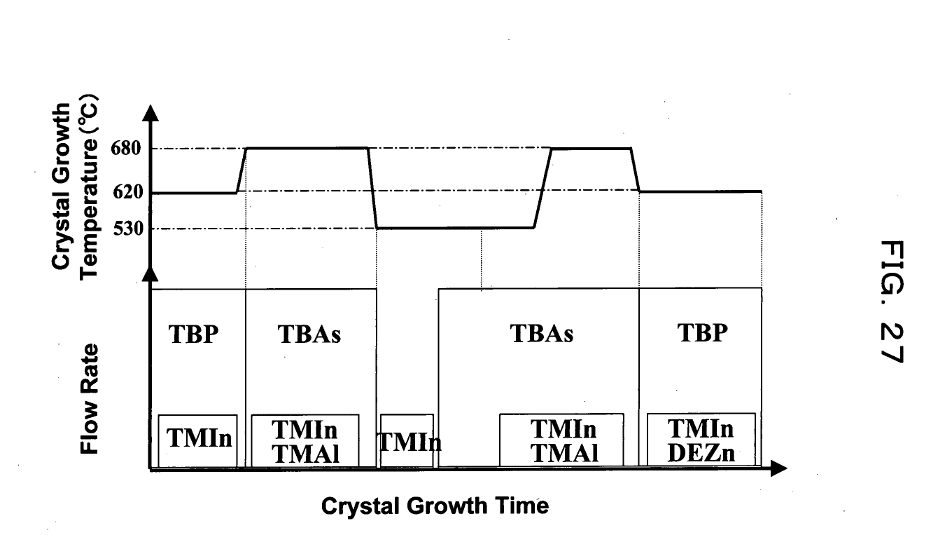

As in Example 4, an LED 15′ was fabricated. The structure of the LED 15′ in this example is identical to that in Example 4 except that the undoped clad layers 16 had a composition of Al_{0.47}In_{0.53}As. An n-type InP substrate 11 of 350 μm thick, with an electron density of 4×10¹⁸ cm⁻³, having a (100) plane and doped with S (sulfur) had grown thereon successively a buffer layer 21 of InP to a thickness of 100 nm, an undoped clad layer 16 to a thickness of 100 nm, a single layer 2 of non-uniform quantum dots of InAs without lattice strain, an undoped clad layer 16 to a thickness of 100 nm and a p-type InP layer 22 to a thickness of 2 μm. Here, the non-uniform quantum dot layer 2 of InAs was grown by the droplet epitaxial growth process and the other layers were grown by the MOCVD process. FIG. 27 is a time chart illustrating a relationship between the growth temperature and the gas flow rate during the crystal growth of an LED 15′ in Example 5. In the graph shown in FIG. 27, the ordinate axis represents both the crystal growth temperature (in ° C.) and the flow rate while the abscissa axis represents the crystal growth time.

At first, using TMIn and TBP the buffer layer 7 of undoped InP was grown to the thickness of 100 nm on the n-type InP substrate 11 with an electron density of 4×10¹⁸ cm⁻³ at the growth temperature of 620° C. TMIn and TBP were supplied at flow rates of 1.68×10⁻⁷ mol/second and 3.38×10⁻⁶ mol/second, respectively. At this point, the supply of TMIn was terminated and the substrate was raised to a temperature of 680° C. while continuing TBP to flow. Next, the supply of TBP was terminated and TMAl, TMIn and TBAs were passed to flow to grow Al_{0.47}In_{0.53}As to the thickness of 100 nm. Then, TMAl, TMIn and TBAs had supply flow rates of 1.68×10⁻⁷ mol/second, 1.67×10⁻⁹ mol/second and 3.38×10⁻⁶ mol/second, respectively. At this point, the supply of TMAl and TMIn was terminated, the substrate temperature was lowered to 530° C. while continuing TBAs to flow, and the supply of TBAs was terminated.

Next, using the droplet epitaxial growth process, a single layer 2a of non-uniform quantum dots of InAs was formed at a temperature of 530° C. as in Example 4 above. Then, TMIn and TBAs were supplied at flow rates of 1.68×10⁻⁷ mol/second and 3.38×10⁻⁶ mol/second, respectively.

Next, after TMIn ceased to be supplied and only TBAs was continued to flow, TMAl and TMIn were again passed to flow to form again Al_{0.47}In_{0.53}As to the thickness of 10 nm. Then, the substrate temperature was again raised to 680° C. to grow again Al_{0.47}In_{0.53}As to the thickness of 90 nm, and TMIn and TMAl ceased to be supplied. Thereafter, the substrate temperature was lowered to 620° C. while passing TBAs to flow, and TBAs ceased to be supplied. Finally, TMIn, TBP and DEZn were supplied at the same flow rates as in Example 2 to grow the p-type InP layer 22 to the thickness of 2 μm.

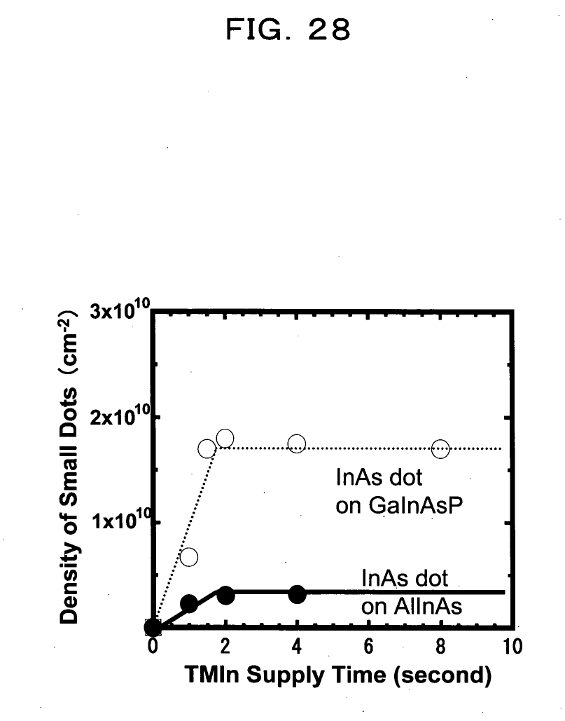

FIG. 28 is a graph illustrating a relationship between the TMIn supply rate and the in-plane density of non-uniform quantum dots in the structure in Example 5. The graph has its abscissa axis representing the TMIn supply time (in second) and its ordinate axis representing the planar density (in cm⁻²) of non-uniform quantum dots. The planar density is of smaller dots. Black circles (●) represent InAs quantum dots on Al_{0.47}In_{0.53}As and white circles (◯) represent InAs quantum dots on In_{0.59}Ga_{0.41}As_{0.89}P_{0.11} in Example 3. The planar density of smaller dots here as that of non-uniform InAs quantum dots on In_{0.59}Ga_{0.41}As_{0.89}P_{0.11} of Example 3 increases linearly as the TMIn supply time runs from 0 to 2 seconds, reaching 3×10⁹ cm⁻². Also, in a time period of 2 to 4 seconds of TMIn supply, the planar density of smaller dots is seen to remain saturated at 3×10⁹ cm⁻², indicating that as with non-uniform InAs quantum dots on In_{0.59}Ga_{0.41}As_{0.89}P_{0.11} in Example 3, the auto-terminating mechanism was brought about. So made, smaller dots when their planar density reached the maximum had an average diameter of 90 nm and an average height of 8 nm.

Also, as with quantum dots of InAs on InP in Examples 1 and 2 and those of InAs on In_{0.59}Ga_{0.41}As_{0.89}P_{0.11} in Example 3, there are formed here both smaller and larger dots. Further, there is found here the tendency that larger quantum dots are not formed until after a time period of 1 second of TMIn supply elapses and their planar density increases linearly in a time period of 1 to 2, reaching 2.5×10⁶ cm⁻² and thereafter remains saturated thereat, similar to that found as with InAs quantum dots on In_{0.59}Ga_{0.41}As_{0.89}P_{0.11} in Example 3.

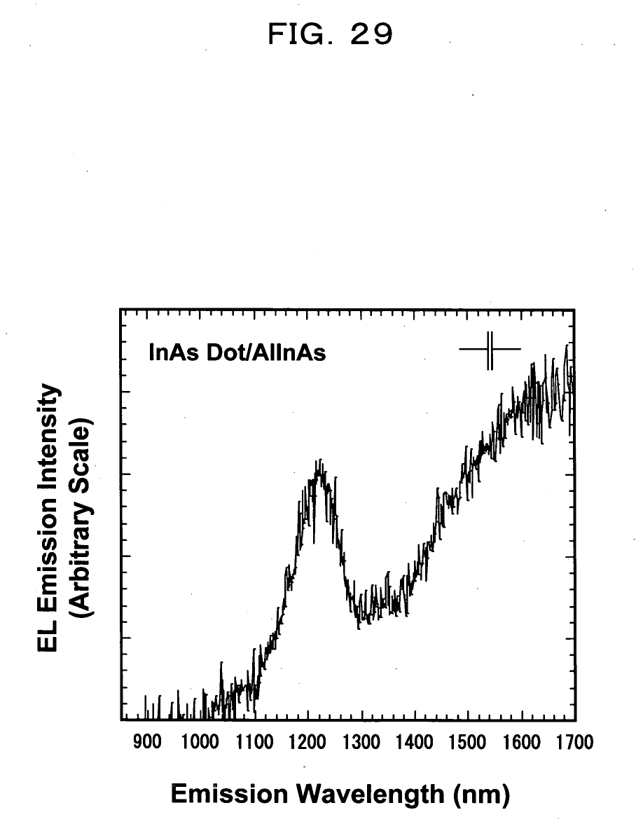

Mention is next made of optical properties of the LED 15′ in Example 5. FIG. 29 is a graph illustrating an EL emission spectrum for forward injection at room temperature, of an LED 15′ using a semiconductor multi-layered structure having non-uniform quantum dots according to Example 5 of the present invention. In the Figure, the graph shown has its abscissa axis along which is plotted the emission wavelength (in nm) and its ordinate axis along which the emission intensity is plotted, wherein the symbol (— | | —) as the width of an emission wavelength indicates its resolution. The detector used in the measurement was a Ge-Pin photo diode. The emission spectrum shown is of the LED 15′ when it was pulse-driven by forward current of 200 mA under the same conditions as in Example 4. The LED 15′ having an area generally of 2 mm×2 mm, the current density is about 5 A/cm².

It is seen that EL light emission of the LED 15′ having a non-uniform quantum dot structure has an emission spectrum of a broad range of ≧1.4 μm. Weak light emission of a 1.2 μm band is due to transitions between positive holes of Al_{0.47}In_{0.53}As and electrons of InP. In an emission spectrum given by PL measurement using a PbS photo diode for the non-uniform quantum dot structure used in this LED 15′, light emissions were observed having a peak emission intensity at about 2.1 μm and having a range of wavelengths up to about 2.4μm (not shown). In Example 5 it is thus seen that the range of wavelengths in EL light emissions has shifted towards longer wavelengths than those in Examples 2 and 3 (see FIGS. 20 and 26). And, smaller quantum dots density in plane being about 4 orders of magnitudes higher than that of larger quantum dots, the emission center is here again seen to be according to smaller non-uniform quantum dots.

The shift of emission wavelengths towards their longer side appears to be due to a drop in electron energy of quantum dots because of increases in average diameter and height of smaller quantum dots of non-uniform InAs quantum dots embedded in Al_{0.47}In_{0.53}As and providing the emission center over those in Examples 2 and 3 (see equation (1) above). From these, it is seen that broadband light emissions of 1.4 μm to 2.4 μm can be obtained from the LED 15′ having non-uniform InAs quantum dots on Al_{0.47}In0.₅₃As in accordance with the present invention.

### EXAMPLE 6

Mention is made of a specific example of semiconductor multi-layered structure grown by MOCVD and droplet epitaxial growth processes for a semiconductor laser diode 20 and a semiconductor light amplifier 30 using the semiconductor multi-layered structure having non-uniform quantum dots which when formed do not requires lattice strain.

For the active layer 3 and clad layers 5, 6, use was made of Al_{0.26}Ga_{0.21}In_{0.53}As and Al_{0.47}In_{0.53}As, respectively. An n-type InP substrate 11 of 350 μm thick, with an electron density of 4×10¹⁸ cm⁻³, having a (100) plane and doped with S (sulfur) had grown thereon successively a buffer layer 21 of InP to a thickness of 100 nm, an n-type clad layer 5 of Al_{0.47}In_{0.53}As to a thickness of 500 nm, an active layer of undoped Al_{0.26}Ga_{0.21}In_{0.53}As to a thickness of 100 nm, a single layer 2 of non-uniform quantum dots without lattice strain, an active layer 3 of undoped Al_{0.26}Ga_{0.21}In_{0.53}As to a thickness of 100 nm, a p-type clad layer 6 of Al_{0.47}In_{0.53}As to a thickness of 500 nm and a p-type InP layer 22 to a thickness of 2 μm.

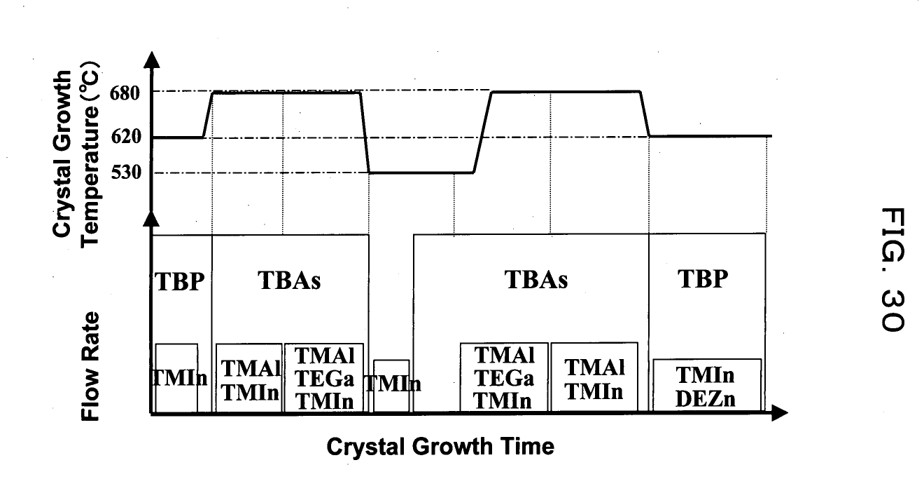

FIG. 30 is a time chart illustrating a relationship between the growth temperature and the gas flow rate during the epitaxial growth of a semiconductor laser diode 20 in Example 6 of the present invention. In FIG. 30, the graph has its ordinate axis representing both the crystal growth temperature (in ° C.) and the rate of flow and its abscissa axis representing the crystal growth time. The buffer layer 21 of InP and the p-type InP layer 22 were epitaxially grown at the temperature of 620° C. and the non-uniform quantum dot layer 2 was epitaxially grown at the temperature of 530° C., as in Example 5. The active layer 3 of Al_{0.26}Ga_{0.21}In_{0.53}As and the clad layers 5 and 6 of Al_{0.26}In_{0.21}In_{0.53}As were epitaxially grown at the temperature of 680° C.

As in Example 5, after growth of the buffer layer 21 of InP the supply of TMIn was terminated and the substrate was raised in temperature from 620° C. to 680° C. while continuing TBP to flow. Immediately upon the temperature rise the supply of TBP was terminated and about 1 second thereafter TBAs was supplied. After lapse of a given time period, TMAl, TMIn and H₂S (not shown) were supplied to form the n-type clad layer 5 of Al_{0.47}In_{0.53}As to the thickness of 500 nm and TMAl, TMIn and H₂S (not shown) ceased to be supplied while continuing TBAs to flow. After lapse of a given time period, TMAl, TEGa and TMIn were supplied to grow Al_{0.26}Ga_{0.21}In_{0.53}As to the thickness of 100 nm and then ceased to be supplied. Next, the substrate temperature was lowered from 680° C. to 530° C. while continuing TBAs to flow. When the temperature dropped to 530° C., TBAs ceased to be supplied. Thereafter, a single layer 2a of non-uniform InAs quantum dots was formed at the temperature of 530° C. using the droplet epitaxial growth process as in Example 4.

The substrate was raised in temperature from 530° C. to 680° C. while passing TBAs to flow. Next, TMAl, TEGa and TMIn were supplied to grow the active layer 3 of Al_{0.26}Ga_{0.21}In_{0.53}As to the thickness of 100 nm. Then, TMAl, TEGa and TMIn ceased to be supplied and a given time period thereafter, TMAl, TMIn and DEZn (not shown) were supplied to grow the p-type clad layer 6 of Al_{0.47}In_{0.53}As to the thickness of 500 nm.

Subsequently, TMAl, TMIn and DEZn ceased to be supplied and the substrate temperature was lowered from 680° C. to 620° C. When the latter temperature was reached, TBAs ceased to be supplied. About 1 second thereafter, the p-type InP layer 22 was grown as in Example 5 to the thickness of 2 μm. Here, during the time periods in which the non-uniform quantum dot layer 2, the active layers 3 of Al_{0.26}Ga_{0.21}In_{0.53}As and the p-type clad layer 6 of Al_{0.47}In_{0.53}As were grown, respectively and the subsequent time period in which the temperature was lowered from 680° C. to 620° C., TBAs was continued to flow constantly.

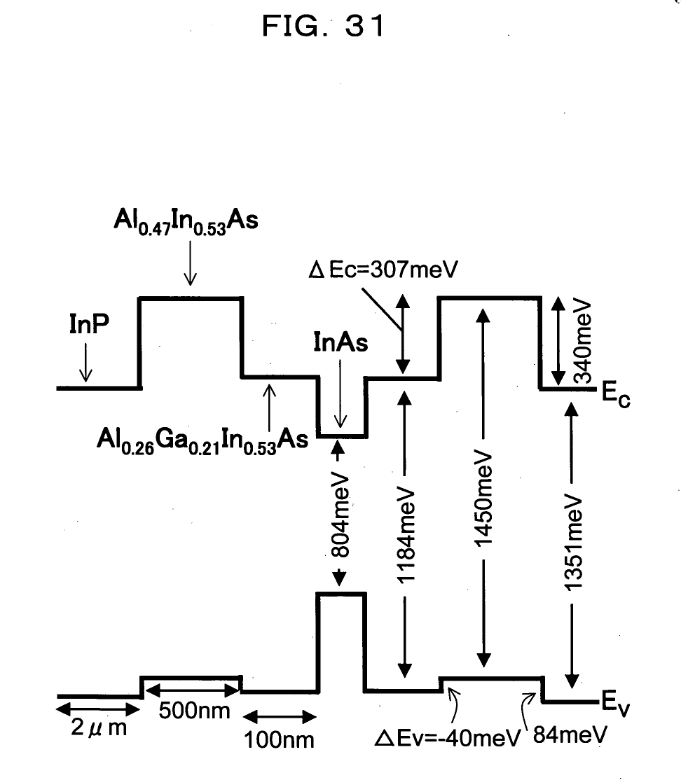

FIG. 31 is a chart illustrating a band structure of a semiconductor laser diode using a semiconductor multi-layered structure having non-uniform quantum dots according to Example 6 of the present invention. As shown, Al_{0.47}In_{0.53}As of the clad layer 5, 6 and Al_{0.26}Ga_{0.21}In_{0.53}As of the active layer 3 have energy difference ΔEc of 231 meV between their conduction bands and energy difference ΔEv of −40 meV between their valence bands (filled bands). It is also shown in the chart that non-uniform quantum dots of InAs have a quantum level of 804 meV. The fact that the value of ΔEc is greater than that of 168 meV when the clad layers 5 and 6 are composed of In_{0.59}Ga_{0.41}As_{0.89}P_{0.11} brings about the advantage that a hetero or non-uniform structure which excels in entrapping electrons can be fabricated. The clad layers 5 and 6 may also be composed of Al_{0.40}Ga_{0.08}In_{0.52}As. In this case, ΔEc and ΔEv are 152 meV and 92 meV, respectively. The clad layers 5 and 6 may thus be made of a material suitably selected according to desired properties of a semiconductor layer diode 20 to be obtained.

On the other hand, clad layers 5 and 6 of Al_{0.47}In_{0.53}As and an active layer 3 of Al_{0.26}Ga_{0.21}In_{0.53}As which contain only one V group element as As make it unnecessary to effect proportional control of more than one V group elements as for As and P in GaₓIn₁₋ₓAs_{y}P_{1-y} when the layers are grown by MOCVD. Also, absence of any other V group element than As in the interfaces between the active layer 3 of Al_{0.26}Ga_{0.21}In_{0.53}As and the non-uniform quantum dots of InAs brings about the advantage that a desired sharpness at those interfaces can readily be assured.

It should be understood that the present invention is not intended to be limited to the specific embodiments thereof set forth above but to include all possible embodiments and various modifications thereof that can be made within the scope with respect to the features specifically set forth in the appended claims. For example, the LD and semiconductor light amplifier described in the preferred embodiments are structurally not limited to be of, e. g., embedding type, with the resonator as well not limited to be a Fabry-Perot resonator but possibly to comprise a lattice grating or the like. Also, while in the specific examples the quantum dots which when formed do not require lattice strain in accordance with the present invention are shown to be of such as InAs or GaₓIn₁₋ₓAs and their double hetero structure is shown to be of a combination such as of Al_{0.47}In_{0.53}As and Al_{0.26}Ga_{0.21}In_{0.53}As, the present invention can, of course, be applied equally to where they are of any other III-V group compound semiconductor including a III group nitride semiconductor, and of any other compound semiconductor such as II-VI or IV-VI compound semiconductor.

### INDUSTRIAL APPLICABILITY

As will be appreciated from the foregoing description, the present invention provides a semiconductor multi-layered structure having non-uniform quantum dots formed without lattice strain, which is rendered capable of multi-wavelength light emission because of excitations from a large number of quantum levels in the structure. The present invention also provides a light emitting diode and a semiconductor laser diode with a semiconductor multi-layered structure having non-uniform quantum dots, which is capable of multi-wavelength light emission. The present invention further provides a semiconductor light amplifier using a semiconductor multi-layered structure having non-uniform quantum dots, which is small in size, light in weight and high in optical gain because of excitations from a large number of quantum levels. The present invention also provides the capability of making a semiconductor multi-layered structure having non-uniform quantum dots, in a novel manner with the use of droplet epitaxial growth process to enable the quantum dots to be formed without lattice strain. The present invention further provides a novel method of making a light emitting diode, a semiconductor laser diode, and a semiconductor light amplifier, each with a semiconductor multi-layered structure having non-uniform quantum dots, with the use of the droplet epitaxial growth process and without resort to the conventional deformation hetero growth process.

1. A semiconductor multi-layered structure having non-uniform quantum dots, characterized in that:
the structure has at least one layer of such quantum dots and;
the quantum dots in the layer are non-uniform quantum dots individually composed of compound semiconductor and different in both of size and compound semiconductor composition, and said non-uniform quantum dots have a plurality of quantum levels as the light emission center by current injection corresponding to multi wavelengths including at least any of ultraviolet, visible light, and infrared light involving 1.3 and 1.5 μm bands.

2. A semiconductor multi-layered structure having non-uniform quantum dots, characterized in that:
it is of a double hetero junction structure comprising an active layer, and a pair of clad layers laid on opposite sides of the active layer and larger in forbidden band than the active layer, and
the active layer includes at least one layer, and each of said non-uniform quantum dots is a non-uniform quantum dot individually composed of compound semiconductor and different in both of size and compound semiconductor composition, and said non-uniform quantum dots have a plurality of quantum levels as the light emission center by current injection corresponding to multi wavelengths including at least any of ultraviolet, visible light, and infrared light involving 1.3 and 1.5 μm bands.

3. (canceled)

4. A semiconductor multi-layered structure having non-uniform quantum dots as set forth in claim 2, characterized in that it is so structured that a plurality of such non-uniform quantum dot layers are embedded in the active layer.

5. A semiconductor multi-layered structure having non-uniform quantum dots as set forth in claim 2 or claim 4, characterized in that:
the quantum dots are made of GaₓIn₁₋ₓAs (where 0<x≦0.6); and
the active layer is made of one of materials selected from the class consisting of InP, AlₓIn₁₋ₓAs (where x=0.27 to 0.65 and it has a forbidden band at room temperature of 0.95 eV to 1.9 eV), GaₓIn₁₋ₓAs_{y}P_{1-y} (where 0<x<1 and 0<y<1), and AlᵤGaᵥIn_{w}As (where u+v+w=1, and it has a forbidden band at room temperature of 0.95 eV to 1.9 eV), and said non-uniform quantum dots have a plurality of quantum levels as the light emission center by current injection corresponding to multi wavelengths including at least either of infrared lights involving 1.3 and 1.5 μm bands.

6. A semiconductor multi-layered structure having non-uniform quantum dots as set forth in claim 2 or claim 4, characterized in that:
the semiconductor multi-layered structure having the non-uniform quantum dots has a substrate made of InP;
the quantum dots are made of GaₓIn₁₋ₓAs (where 0<x≦0.6);
the active layer is made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV); and
the clad layers are made of AlₓIn₁₋ₓAs (where x=0.42 to 0.48 and it has a forbidden band at room temperature of 1.3 eV to 1.46 eV) or AlₓGa_{y}In_{z}As (where x+y+z=1, and it has a forbidden band at room temperature of 1.3 eV to 1.46 eV), and said non-uniform quantum dots have a plurality of quantum levels as the light emission center by current injection corresponding to multi wavelengths including at least either of infrared lights involving 1.3 and 1.5 μm bands.

7. A semiconductor multi-layered structure having non-uniform quantum dots as set forth in claim 2 or claim 4, characterized in that the active layer is lattice-matching with the clad layers.

8. A light emitting diode using a semiconductor multi-layered structure having non-uniform quantum dots, characterized in that:
it comprises a p-type semiconductor layer and an n-type semiconductor layer which together form a pn diode; and a layer of non-uniform quantum dots contained in either a p-type or an n-type semiconductor layer,
each of said quantum dots is a non-uniform quantum dot individually composed of compound semiconductor and different in both of size and compound semiconductor composition, and said non-uniform quantum dots have a plurality of quantum levels as the light emission center by current injection corresponding to multi wavelengths including at least any of ultraviolet, visible light, and infrared light involving 1.3 and 1.5 μm bands,
whereby injecting current into said pn diode causes the non-uniform quantum dots to be excited, thereby emitting light therefrom in a multi of predetermined wavelengths.

9. A light emitting diode using a semiconductor multi-layered structure having non-uniform quantum dots, characterized in that:
it comprises an active layer containing a semiconductor multi-layered structure having non-uniform quantum dots; and
a double hetero junction structure comprising the active layer and clad layers formed at opposite sides of the active layer and larger in forbidden band than the active layer,
each of said quantum dots is a non-uniform quantum dot individually composed of compound semiconductor and different in both of size and compound semiconductor composition, and said non-uniform quantum dots have a plurality of quantum levels as the light emission center by current injection corresponding to multi wavelengths including at least any of ultraviolet, visible light, and infrared light involving 1.3 and 1.5 μm bands,
whereby injecting current into the double hetero junction structure causes the non-uniform quantum dots to be excited, thereby emitting light in a muti of predetermined wavelengths.

10. (canceled)

11. (canceled)

12. A light emitting diode using a semiconductor multi-layered structure having non-uniform quantum dots as set forth in claim 8 or claim 9, characterized in that said light emitting diode has a substrate made of InP; and said quantum dots are made of GaₓIn₁₋ₓAs (where 0<x≦0.6).

13. A light emitting diode using a semiconductor multi-layered structure having non-uniform quantum dots as set forth in claim 9, characterized in that
said quantum dots are made of GaₓIn₁₋ₓAs (where 0<x≦0.6); and
said active layer is made of one of materials selected from the class consisting of InP, AlₓIn₁₋ₓAs (where x=0.27 to 0.65 and it has a forbidden band gap at room temperature of 0.95 eV to 1.9 eV), GaₓIn₁₋ₓAs_{y}P_{1-y} (where 0<x<1 and 0<y<1), and AlᵤGaᵥIn_{w}As (where u+v+w=1, and it has a forbidden band gap at room temperature of 0.95 eV to 1.9 eV).

14. A light emitting diode using a semiconductor multi-layered structure having non-uniform quantum dots as set forth in claim 9, characterized in that:
the light emitting diode has a substrate made of InP;
the quantum dots are made of GaₓIn₁₋ₓAs (where 0<x≦0.6);
the active layer is made of AlₓIn₁₋ₓAs (where x=0.27 to 0.40 and it has a forbidden band gap at room temperature of 0.95 eV to 1.24 eV) or AlᵤGaᵥIn_{w}As (where u+v+w=1, and it has a forbidden band gap at room temperature of 0.95 eV to 1.24 eV); and
the clad layers are made of InP.

15. A semiconductor laser diode using a semiconductor multi-layered structure having non-uniform quantum dots, characterized in that:
it comprises an active layer containing at least one layer of non-uniform quantum dots; and
a double hetero junction structure comprising the active layer and clad layers formed at opposite sides of the active layer and larger in forbidden band gap than the active layer,
each of said quantum dots is a non-uniform quantum dot individually composed of compound semiconductor and different in both of size and compound semiconductor composition, and said non-uniform quantum dots have a plurality of quantum levels as the light emission center by current injection corresponding to multi wavelengths including at least any of ultraviolet, visible light, and infrared light involving 1.3 and 1.5 μm bands,
whereby injecting current into the double hetero junction structure causes the non-uniform quantum dots to be excited, thereby bringing about laser oscillations in a multi of predetermined wavelengths.

16. (canceled)

17. (canceled)

18. A semiconductor laser diode using a semiconductor multi-layered structure having non-uniform quantum dots as set forth in claim 15, characterized in that
the semiconductor laser diode has a substrate made of InP;
the quantum dots are made of GaₓIn₁₋ₓAs (where 0<x≦0.6);
the active layer is made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV); and
the clad layers are made of AlₓIn₁₋ₓAs (where x=0.42 to 0.48 and it has a forbidden band at room temperature of 1.3 eV to 1.46 eV) or AlₓGa_{y}In_{z}As (where x+y+z=1, and it has a forbidden band at room temperature of 1.3 eV to 1.46 eV).

19. A semiconductor laser diode using a semiconductor multi-layered structure having non-uniform quantum dots as set forth in claim 15 or claim 18, characterized in that the active layer is lattice-matching with the clad layers.

20. A semiconductor light amplifier using a semiconductor multi-layered structure having non-uniform quantum dots, characterized in that:
it comprises an active layer containing at least one layer of non-uniform quantum dots; and
a double hetero junction structure comprising the active layer and clad layers formed at opposite sides of the active layer and larger in forbidden band than the active layer,
each of said quantum dots is a non-uniform quantum dot individually composed of compound semiconductor and different in both of size and compound semiconductor composition, and said non-uniform quantum dots have a plurality of quantum levels as the light emission center by current injection corresponding to multi wavelengths including at least any of ultraviolet, visible light, and infrared light involving 1.3 and 1.5 μm bands,
whereby injecting current into the double hetero junction structure causes the non-uniform quantum dots to be excited, thereby amplifying light in a multi of predetermined wavelengths incident externally of the double hetero junction structure.

21. (canceled)

22. (canceled)

23. A semiconductor light amplifier using a semiconductor multi-layered structure having non-uniform quantum dots as set forth in claim 20, characterized in that
the semiconductor light amplifier has a substrate made of InP; the quantum dots are made of GaₓIn₁₋ₓAs (where 0<x≦0.6);
the active layer is made of AlₓIn₁₋ₓAs (where x=0.27 to 0.40 and it has a forbidden band at room temperature of 0.95 eV to 1.24 eV) or AlᵤGaᵥIn_{w}As (where u+v+w=1, and it has a forbidden band at room temperature of 0.95 eV to 1.24 eV); and
the clad layers are made of AlₓIn₁₋ₓAs (where x=0.42 to 0.48 and it has a forbidden band at room temperature of 1.3 eV to 1.46 eV) or AlₓGa_{y}In_{z}As (where x+y+z=1, and it has a forbidden band at room temperature of 1.3 eV to 1.46 eV).

24. A semiconductor light amplifier using a semiconductor multi-layered structure having non-uniform quantum dots as set forth in claims 20 or claim 23, characterized in that the active layer is lattice-matching with the clad layers.

25. A method of making a semiconductor device using a semiconductor multi-layered structure having non-uniform quantum dots in a non-uniform quantum dot structure, characterized in that it includes the step of fabricating the non-uniform quantum dot structure for the semiconductor device by an epitaxial growth process that does not require lattice strain in forming non-uniform quantum dots, and said non-uniform quantum dot structure of a semiconductor device is formed by epitaxial growth process without requiring lattice strain, and in this case, said non-uniform quantum dot structure is formed by auto-termination mechanism of a droplet epitaxial growth process using either of MOCVD, MBE, gas source MBE, or MOMBE method.

26. A method of making a semiconductor device using a semiconductor multi-layered structure having non-uniform quantum dots as set forth in claim 25, characterized in that said semiconductor device is any one of a light emitting diode, a semiconductor laser diode and a semiconductor light amplifier.

27. A method of making a semiconductor device using a semiconductor multi-layered structure having non-uniform quantum dots as set forth in claim 25 or claim 26, characterized in that said non-uniform quantum dot structure of a semiconductor device is a non-uniform quantum dot individually composed of compound semiconductor and different in either one or both of size and compound semiconductor composition.

28. A method of making a semiconductor device using a semiconductor multi-layered structure having non-uniform quantum dots as set forth in claim 27, characterized in that said quantum dot structure consists of InAs, or GaₓIn₁₋ₓAs (where 0<x≦0.6).

29. A method of making a semiconductor device using a semiconductor multi-layered structure having non-uniform quantum dots as set forth in claim 25, characterized in that said epitaxial growth process is MOCVD and the non-uniform quantum dot layer is formed by droplet epitaxial growth at a growth temperature lower than that at which other growth layers in the structure are formed.

30. A semiconductor device, characterized in that it is manufactured by the method of manufacture of semiconductor devices using a semiconductor multi-layered structure having non-uniform quantum dots as set forth in claim 25 or claim 26.
